(19) United States
(12) Patent Application Publication
(10) Pub. No.: US 2024/0203990 A1
(43) Pub. Date: Jun. 20, 2024

(54) STACKED CMOS DEVICES WITH TWO DIELECTRIC MATERIALS IN A GATE CUT

(71) Applicant: International Business Machines Corporation, Armonk, NY (US)

(72) Inventors: Ruilong Xie, Niskayuna, NY (US); Kangguo Cheng, Schenectady, NY (US); Julien Frougier, Albany, NY (US); Chanro Park, Clifton Park, NY (US); Min Gyu Sung, Latham, NY (US)

(21) Appl. No.: 18/065,860

(22) Filed: Dec. 14, 2022

(51) Int. Cl. H01L 27/092; H01L 21/28; H01L 21/822; H01L 21/8238; H01L 29/06; H01L 29/417; H01L 29/423; H01L 29/66; H01L 29/775

(52) U.S. Cl. CPC H01L 27/0922; H01L 21/28123; H01L 21/8221; H01L 21/823807; H01L 21/823814; H01L 21/823828; H01L 21/823871; H01L 21/823878; H01L 29/0673; H01L 29/41733; H01L 29/42392; H01L 29/66439; H01L 29/66545; H01L 29/775

(57) ABSTRACT

A complementary field effect transistor (CFET) device is formed on a semiconductor substrate. The CFET device has a first transistor that is under a second transistor. A filled gate cut is directly adjacent to the sidewall of the gate of the CFET device. The first dielectric material in the gate cut is adjacent to the first transistor. The second dielectric material in the gate cut is adjacent to the second transistor. The two dielectric materials in the gate cut are selected to improve the electrical performance of each of the NFET and the PFET in the CFET device. The first dielectric material can apply a compressive stress to the channels of the first transistor when the first transistor is a PFET to improve the electrical performance of the PFET. When the second transistor is an NFET, the second dielectric material applies a tensile stress to NFET to improve NFET performance.

### BACKGROUND

The disclosure relates generally to nanosheet transistors. The disclosure relates particularly to complementary field-effect transistors (CFETs) formed with two dielectric materials in a gate cut between two adjacent CFET devices.

As the semiconductor industry technology continues scaling according to Moore's law, significant challenges arise as the industry looks beyond the 5 nm technology node. With increasing demands to reduce the dimensions of transistor devices, nanosheet field-effect transistors (FETs) help achieve a reduced device footprint while maintaining device performance. A nanosheet FET device contains one or more portions of layers of semiconductor channel material having a vertical thickness that is substantially less than its width. A typical nanosheet FET includes a plurality of stacked nanosheets extending between a pair of source/drain epitaxial regions. The nanosheet FET device may be a gate-all-around device in which a gate surrounds the channels of the nanosheet FET devices.

The gate-all-around (GAA) nanosheet metal-oxide-semiconductor field-effect transistor (MOSFET) structures have been recognized as excellent candidates to achieve improved power performance and area scaling compared to the current FinFET technologies. Specifically, nanosheet-based semiconductor structures such as GAA nanosheet MOSFETs provide high drive currents due to wide effective channel width (Weff) while maintaining short-channel control.

The complementary field-effect transistor (CFET) is composed of two stacked complementary FETs, where the stacked complementary FET includes a p-type FET (PFET) and an n-type FET (NFET) that are vertically stacked. The CFET devices provide a further evolution of the gate-all-around (GAA) nanosheet transistor. Instead of stacking either n-type devices on top of other n-type devices or stacking p-type devices on other p-type devices as occurs with conventional vertically stacked GAA nanosheet transistors, CFET devices stack both n-type and p-type devices on top of each other. CFET stacked transistors offer a scaling path by stacking the NFET and PFET over each other, thereby providing an area benefit. Combined with appropriate interconnects, the CFET approach can effectively cut an inverter footprint in half, doubling the area density and further pushing the limits of Moore's Law.

However, CFET devices create unique device mobility concerns with the stacked NFET and PFETs in the CFET devices because the various layers of the nanosheets forming the CFET are epitaxially grown from the semiconductor substrate or wafer with the crystal orientation as the semiconductor substrate. The typical nanosheet architecture places the (100) crystal plane of the nanosheets parallel to the substrate, as opposed to the (110)-oriented channel in finFETs. Using the (100) plane for both transistors of the CFET changes both the absolute and relative mobilities of electrons and holes in the channels of the transistors. In CFET devices with an NFET and a PFET, Si wafers with channels in the (100) crystal plane can be used to form the nanosheets to deliver the highest electron mobility for the n-type transistors (NFETs) while the p-type transistors (PFETs) face challenges in electron hole mobility that is needed for optimal PFET performance due to the (100) crystal plane orientation of the channel material.

### SUMMARY

The following presents a summary to provide a basic understanding of one or more embodiments of the disclosure. This summary is not intended to identify key or critical elements or delineate any scope of the particular embodiments or any scope of the claims. Its sole purpose is to present concepts in a simplified form as a prelude to the more detailed description that is presented later.

Aspects of the disclosed invention relate to the semiconductor device structure of a complementary field effect transistor (CFET) device on a semiconductor substrate where the CFET device has a first transistor that is under a second transistor. The first transistor and the second transistor create a stacked pair of transistors composed of an NFET and PFET forming the CFET device. A filled gate cut is directly adjacent and abutting a gate of the CFET device. Aspects of the present invention disclose that the gate cut is filled with a first dielectric material under a second dielectric material where the first dielectric material is adjacent to the first transistor and the second dielectric material is adjacent to the second transistor. The two dielectric materials in the gate cut are selected to improve the electrical performance of each of the n-type FET (NFET) and the p-type FET (PFET) in the CFET device. In CFET devices, neither the bottom source/drain nor the top source/drain cans generate adequate strain to the channels of either the stacked NFET or the stacked PFET to create sufficient electron or hole mobilities for optimal FET performance. Therefore, aspects of the present invention disclose CFET devices with a new structure using a filled gate cut directly adjacent to the CFET device that enhances the hole mobility in the PFET channel by applying a compressive stress to the PFET channels and improves the electron mobility in an NFET channel by applying a tensile stress improves NFET performance.

Embodiments of the present invention provide a first dielectric material in the gate cut that applies one of a compressive stress or a tensile stress to the channels of the first transistor. When the first transistor is an NFET, the first dielectric material applies a tensile stress to the channels of the first transistor, then the second dielectric material is selected to apply a compressive stress to the channels of the second transistor which is a PFET in the CFET device. Aspects of the present invention also disclose that the first dielectric material in the gate cut applies the compressive stressor to the channels of the first transistor when the first transistor is a PFET to improve the electrical performance of the PFET by increasing hole mobility. When the first transistor is a PFET, then the second transistor is an NFET and the second dielectric material in the gate cut applies a tensile stress to the channels of the NFET to improve the electron mobility in the channels of the NFET. Improving the electron mobility in the channels of the NFET improves the NFET electrical performance.

Aspects of the present invention disclose that the gate cut filled with the first dielectric material and the second dielectric material that are between the gates of at least two adjacent complementary field-effect transistor devices in two adjacent cells where the first and the second dielectric material are selected to apply the appropriate stress to improve PFET and NFET electrical performance in each of the adjacent CFET devices.

Aspects of the present invention disclose a method of forming a complementary field-effect transistor (CFET) device. The method includes epitaxially growing a nanosheet stack on a semiconductor substrate and selectively etching portions of the nanosheet stack and a top portion of the semiconductor substrate. The method includes forming shallow trench isolations (STI) in the semiconductor substrate adjacent to the remaining portions of the nanosheet stack. The method includes forming at least two stacked gate-all-around field-effect transistors separated by a middle dielectric isolation material on the semiconductor substrate, where at least a first transistor is under the middle dielectric isolation material and at least a second transistor is above the middle dielectric isolation material. The method includes performing gate cuts through a portion of each gate that is between adjacent first transistors and adjacent second transistors. The gate cuts go through the STI adjacent to the first transistor and the top portion of the semiconductor substrate. The method includes filling the gate cuts with a first dielectric material and recessing the first dielectric material where the first dielectric material is selected to create a compressive stress if the first transistor is a PFET or is selected to provide a tensile stress if the first transistor is an NFET. The method includes depositing a second dielectric material where the second dielectric material is selected to apply a tensile stress if the second transistor is an NFET or a compressive stress if the second transistor is a PFET. The method includes performing a planarization to remove the excess or overburden of the second dielectric material.

Aspects of the present invention disclose a semiconductor structure with a plurality of cells of complementary field-effect transistor (CFET) devices, where each of the CFET devices have a first transistor that is under a second transistor. The semiconductor structure includes a first dielectric material abutting a portion of each channel in the first transistor in a first CFET device in a first cell and abutting a portion of each channel in the first transistor in a second CFET device in a second cell of the CFET devices. The first cell of the CFET devices is adjacent to the second cell of the CFET devices. The first dielectric material has a fixed charge with a first polarity. The semiconductor structure includes a second dielectric material abutting a portion of each channel in the second transistor in the first CFET device of the first cell of CFET devices and abutting a portion of each channel in the second transistor in the second CFET device of the second cell of CFET devices. The second dielectric material has the fixed charge with a second polarity. The second dielectric material abutting the second transistor resides on the first dielectric material abutting the first transistor. The first dielectric material and the second dielectric material are selected with a fixed polarity to improve the electrical performance of NFETs and PFETs in each of the first CFET device and the second CFET device.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a cross-sectional view of a semiconductor structure after forming a nanosheet stack on the semiconductor substrate, in accordance with an embodiment of the present invention.

FIG. 2 depicts a cross-sectional view of the semiconductor structure after patterning the nanosheet stack and forming shallow trench isolation (STI), in accordance with an embodiment of the present invention.

FIG. 3 depicts a top view of the semiconductor structure after forming stacked field-effect transistors (FETs) of adjacent CFET devices with an active area and a gate in three cells, in accordance with an embodiment of the present invention.

FIG. 3A depicts a cross-sectional view of the semiconductor structure in the X-X direction depicted in FIG. 3 after forming the stacked FETs of adjacent CFET devices with the bottom and top S/D and the gate in a cell, in accordance with an embodiment of the present invention.

FIG. 3B depicts a cross-sectional view of the semiconductor structure in the Y-Y direction depicted in FIG. 3 after forming the stacked FETs in adjacent CFET devices with the bottom and top S/D and the gate, in accordance with an embodiment of the present invention.

FIG. 4 depicts a top view of the semiconductor structure of FIG. 3 after forming a cut in each of the gates, in accordance with an embodiment of the present invention.

FIG. 4A depicts a cross-sectional view of the semiconductor structure in the X-X direction depicted in FIG. 4 after forming the cut in each of the gates, in accordance with an embodiment of the present invention.

FIG. 4B depicts a cross-sectional view of the semiconductor structure in the Y-Y direction depicted in FIG. 4 after forming the cut in each of the gates, in accordance with an embodiment of the present invention.

FIG. 5A depicts a cross-sectional view of the semiconductor structure in the X-X direction after depositing a first dielectric material, in accordance with an embodiment of the present invention.

FIG. 5B depicts a cross-sectional view of the semiconductor structure in the Y-Y direction after depositing the first dielectric material, in accordance with an embodiment of the present invention.

FIG. 6A depicts a cross-sectional view of the semiconductor structure in the X-X direction after performing a chemical-mechanical polish (CMP) and removing a portion of the first dielectric material in each gate cut, in accordance with an embodiment of the present invention.

FIG. 6B depicts a cross-sectional view of the semiconductor structure in the Y-Y direction after performing a CMP and removing the portion of the first dielectric material in each gate cut, in accordance with an embodiment of the present invention.

FIG. 7A depicts a cross-sectional view of the semiconductor structure in the X-X direction after depositing a second dielectric material and performing a CMP, in accordance with an embodiment of the present invention.

FIG. 7B depicts a cross-sectional view of the semiconductor structure in the Y-Y direction after depositing the second dielectric material and performing the CMP, in accordance with an embodiment of the present invention.

FIG. 8A depicts a cross-sectional view of the semiconductor structure in the X-X direction after depositing a frontside interlayer dielectric (ILD), forming frontside contacts with frontside interconnect layers, carrier wafer bonding, semiconductor substrate removal, depositing a backside ILD, forming backside contacts to the bottom S/D, and forming backside interconnect layers, in accordance with an embodiment of the present invention.

FIG. 8B depicts a cross-sectional view of the semiconductor structure in the Y-Y direction after depositing the frontside interlayer dielectric (ILD), forming frontside contacts with frontside interconnect layers, carrier wafer bonding, semiconductor substrate removal, depositing the backside ILD, forming backside contacts to the bottom S/D, and forming backside interconnect layers, in accordance with an embodiment of the present invention.

FIG. 9 depicts a cross-sectional view of the semiconductor structure through and parallel to a gate after etching the nanosheet stack to form STI and a gate structure, in accordance with an embodiment of the present invention.

FIG. 10 depicts a top view of the semiconductor structure of FIG. 10 after forming a cut bisecting each active area and in the gate between the remaining portions of the channel material the active areas, in accordance with an embodiment of the present invention.

FIG. 10A depicts a cross-sectional view of the semiconductor structure in the X-X direction depicted in FIG. 10 after forming the cut in the active areas and in the gate between the remaining portions of the channel material, in accordance with an embodiment of the present invention.

FIG. 10B depicts a cross-sectional view of the semiconductor structure in the Y-Y direction depicted in FIG. 10 after forming the cut in each the active areas and in the gate between the remaining portions of the channel material, in accordance with an embodiment of the present invention.

FIG. 11A depicts a cross-sectional view of the semiconductor structure in the X-X direction depicted in FIG. 10 after depositing a first dielectric material in the cuts, performing a chemical-mechanical polish (CMP), and removing a top portion of the first dielectric material in each cut, in accordance with an embodiment of the present invention.

FIG. 11B depicts a cross-sectional view of the semiconductor structure in the Y-Y direction depicted in FIG. 10 after depositing the first dielectric material, performing a CMP, and removing the top portion of the first dielectric material in each cut, in accordance with an embodiment of the present invention.

FIG. 12A depicts a cross-sectional view of the semiconductor structure in the X-X direction after depositing a second dielectric material, performing a CMP, in accordance with an embodiment of the present invention.

FIG. 12B depicts a cross-sectional view of the semiconductor structure in the Y-Y direction after depositing the second dielectric material and performing the CMP, in accordance with an embodiment of the present invention.

FIG. 13A depicts a cross-sectional view of the semiconductor structure in the X-X direction after depositing a frontside interlayer dielectric (ILD), forming frontside contacts with frontside interconnect layers, carrier wafer bonding, semiconductor substrate removal, depositing a backside ILD, forming backside contacts to the bottom S/D, and forming backside interconnect layers, in accordance with an embodiment of the present invention.

FIG. 13B depicts a cross-sectional view of the semiconductor structure in the Y-Y direction after depositing the frontside interlayer dielectric (ILD), forming frontside contacts with frontside interconnect layers, carrier wafer bonding, semiconductor substrate removal, depositing the backside ILD, forming backside contacts to the bottom S/D, and forming backside interconnect layers, in accordance with an embodiment of the present invention.

### DETAILED DESCRIPTION

Embodiments of the present invention recognize that in following Moore's law, numerous technological strides have been made in the semiconductor industry to create even smaller transistors, fitting more transistors in the same area, while reducing the power consumption of these evolving transistors and resulting semiconductor devices. For the evolution of reduced size transistors, semiconductor technology has evolved from planar transistor designs to three-dimensional type finFET designs which are further evolving into gate-all-around transistor designs. Embodiments of the present invention recognize that 3D-stacked complementary metal-oxide semiconductor (CMOS) devices and CFET (complementary field-effect transistor) devices will be the key to continuing to extend Moore's Law.

Embodiments of the present invention recognized that complementary field-effect transistors (CFETs), provide a further evolution of the gate-all-around (GAA) nanosheet transistor by stacking NFETs and PFETs in the same CFET device. Embodiments of the present invention recognize that the CFET approach of vertically stacking GAA NFETs and GAA PFETs formed using stacked epitaxially formed nanosheets of semiconductor materials can provide significant area advantages compared to conventional planar and fin FET devices. Specifically, embodiments of the present invention recognize that CFET devices using backside interconnections offer more routing options for the stacked FETs with more relaxed congestion in the middle-of-line (MOL) and back end of line (BEOL) interconnect layers. However, embodiments of the present invention recognize that for a CFET formed using a stacked NFET and a PFET formed from semiconductor nanosheets and backside interconnects, neither bottom S/D epi nor top S/D epi can generate adequate strain to the channels, therefore, the performance of the stacked FETs in CFET devices is a concern due to low electron or hole mobilities due to the lack of channel strain. Strain is the deformation or displacement of material that results from an applied stress where the stress is the force applied to a material, divided by the material's cross-sectional area.

Embodiments of the present invention provide a semiconductor structure and a method of the semiconductor structure that provides an optimal channel strain for the channels in both the NFETs and the PFETs stacked in adjacent CFET devices. Embodiments of the present invention disclose creating a gate cut between adjacent CFET devices. The gate cut extends from a top surface of the gate of the complementary field-effect transistor device through a shallow isolation trench into a top portion of a semiconductor substrate under the complementary field-effect transistor device. The gate cut is filled with two dielectric materials where one dielectric material is capable of providing an appropriate stress to the channels of the NFET and the second dielectric material provides the appropriate stress to the channels of the PFET. One dielectric material in the gate cut is selected to provide a compressive stress to PFET channels adjacent to the gate cut and a second dielectric material in the gate cut is adjacent to the NFET channels. The second dielectric material is selected to provide a tensile stress to NFET channels.

More specifically, embodiments of the present invention provide a first dielectric material in the bottom portion of the gate cut adjacent to the first FET of the stacked FETs and a second dielectric material on the first dielectric material in the gate adjacent to the second transistor of the stacked FETs of the adjacent CFET devices. The first dielectric material is selected with a composition that can provide the compressive stress to the first transistor if the first transistor is a PFET or the first dielectric material is selected to have a composition that provide the tensile stress to the first transistor if the first transistor is an NFET. Similarly, embodiments of the present invention provide the second dielectric material in the gate cut between adjacent CFET devices that can provide a compressive stress to the second device formed as a PFET or a tensile stress to the second device formed as an NFET.

In this way, embodiments of the present invention can provide improved or optimal performance of both the PFETs and the NFETs in CFET devices. Applying a compressive stress to the channels of PFETs in the CFET devices with the dielectric material used to fill the gate directly adjacent to the PFET improves hole mobility of the PFET. Similarly, applying a tensile stress to the channels of NFETs in the CFET devices with a tensile stress generating dielectric material in the gate cut adjacent to an NFET improves the electron mobility of the NFET and, thereby, improves the electrical performance of the NFETs in a CFET device.

In another aspect, embodiments of the present invention improve the packing density of CFET devices, a semiconductor structure and methods of forming the semiconductor structure with reduced cell size for CFET devices by removing a portion of the gate extension between adjacent CFET devices in adjacent cells. The semiconductor structure allows tighter cell-to-cell separation or spacing between adjacent cells of CFET devices while still providing robust cell-to-cell electrical isolation. Embodiments of the present invention provide a gate cut that simultaneously bisects the remaining portions of the nanosheet channels of the transistors in CFET devices in two adjacent cells. In this, way, the gate extensions are not formed abutting the gate cut allowing closer spacing of adjacent CFET devices around the gate cut. The gate cut is filled with a two dielectric materials to improve the electrostatics in the region of the transistor channels not covered by the gate structure.

The semiconductor structure for the CFET devices providing tighter cell-to-cell spacing occurs by removing a portion of the gate extension on facing sidewalls of adjacent CFET devices. The adjacent CFET devices are in adjacent cells of the CFET devices. The gate extension typically adds approximately ten nanometers to a side of each CFET device. Removing a portion of the gate extensions from the sidewalls of two adjacent CFET devices provides a significant reduction of the space between the sidewalls of the two CFET devices (approximately, twenty nanometers reduction in the distance CFET to CFET of the exposed channels of the two CFET devices but is not limited to this spacing reduction).

Providing a semiconductor structure and a method of forming the semiconductor structure without a gate extension between two adjacent CFET devices in adjacent cells of the CFET devices significantly reduces the footprint of the adjacent CFET devices and the footprint of multiple cells of CFET devices without gate extensions.

Additionally, aspects of the present invention provide two dielectric materials in the gate cut abutting the exposed portions of the channels of both transistors in the adjacent CFET devices without a portion of the gate extension. Using two different dielectric materials to fill the gate cut where each dielectric material is selected with a fixed charge to improve the electrostatics in the type of transistor channels (e.g., NFET or PFET) the dielectric material in the gate cut abuts.

Using this semiconductor structure and the method of forming the semiconductor structure, the electrical performance of both the NFETs and the PFETs in the CFET devices in the region without the gate extension can be improved. By filling the gate cut abutting the portion of the channels of each of the top and the bottom transistors in the CFET devices without a portion of the gate extension with a dielectric material with a fixed charge that improves the performance of each specific type of transistors. More specifically, aspects of the present invention disclose using a dielectric material with a positive fixed charge in the bottom portion of the gate cut directly adjacent to the exposed surfaces of the channels of the bottom transistor when the bottom transistor is a PFET. The positively charged dielectric material abuts both of the bottom PFET transistors on the two facing sides of the gate cut. Similarly, if the bottom transistor is a NFET, the bottom dielectric material abutting the exposed portions of the channels of both of the CFET devices directly adjacent to the gate cut is selected to have a negative fixed charge.

The top dielectric material in the gate cut resides on the bottom dielectric material in the gate cut. The top dielectric material in the gate cut directly abuts the exposed portions of the channels in the top two transistor of the CFET devices in two cell directly adjacent to the gate cut. The portions of the channels exposed by the gate cut adjacent to the top transistor are without contact with the gate and therefore, as previously discussed, have reduced electrical performance. For example, when the top transistor is an NFET, a selection of a negatively charged dielectric material for the top dielectric can occur to improve the electrical performance the two NFET transistors abutting the top dielectric material. The top dielectric material a polarity or fixed negative charge improves electrical performance in the two adjacent transistors when the bottom transistors are NFETs.

When the top transistors in the CFET devices abutting the gate cut in adjacent cells are NFETs, the bottom transistor is a PFET. In this case, the bottom dielectric material abutting the bottom transistors (i.e., PFETs) has a different fixed charge with a polarity that improves the electrical performance of the PFETs in the CFET devices. The bottom dielectric material abutting the channels of a PFET provides a fixed positive charge to the exposed edges of the channels of the bottom transistors.

Alternatively, when the top transistors in the CFET devices of adjacent cells are PFETs, then the dielectric material abutting the exposed edges of the channels of the top transistor can have a positive fixed charge to improve the electrical performance of the PFET. When the top transistors are PFETs, the bottom transistors adjacent to the gate cut will be NFETs and, in this case, the exposed edges of the channels of the NFETs abutting the bottom dielectric material in the gate cut has a negative fixed charge.

Embodiments of the present invention provide a first dielectric material in the gate cut with a fixed positive charge adjacent to exposed portions of the channels of PFETs in the CFET devices abutting the gate cut between adjacent CFET cells and a second dielectric material with a negative fixed charge in the gate cut abutting the exposed channels of the NFET in the CFET devices of the adjacent cells of CFET devices. Using this method of forming the CFET devices in adjacent cells, where the exposed channels of the NFETs and the PFETs contact a dielectric material with an appropriate fixed charge, improves the electrical performance of NFET and PFET devices in the regions without a gate extension while also providing a reduction in the space between the CFET devices in the adjacent cells.

Some embodiments will be described in more detail with reference to the accompanying drawings, in which the embodiments of the present disclosure have been illustrated. However, the present disclosure can be implemented in various manners, and thus should not be construed to be limited to the embodiments disclosed herein.

It is to be understood that aspects of the present invention will be described in terms of a given illustrative architecture; however, other architectures, structures, substrate materials, process features, and steps can be varied within the scope of aspects of the present invention.

It will also be understood that when an element such as a layer, region, or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Methods as described herein can be used in the fabrication of integrated circuit chips also known as a semiconductor chip. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

The terminology used herein is for the purpose of describing particular embodiments only and is not tended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for case of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below,” or “beneath” other elements or features would then be oriented “above” the other elements or features. Thus, the term “below” can encompass both an orientation of above and below. The device can be otherwise oriented (rotated 90 degrees or at other orientations and the spatially relative descriptors used herein can be interpreted accordingly. In addition, be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

Deposition processes for the metal materials and sacrificial material include, e.g., chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include, but are not limited to, atmospheric pressure CVD (APCVD), low-pressure CVD (LPCVD), plasma enhanced CVD (PECVD), and metal-organic CVD (MOCVD), and combinations thereof may also be employed. In alternative embodiments that use ALD, chemical precursors react with the surface of a material one at a time to deposit a thin film on the surface. In alternative embodiments that use gas cluster ion beams (GCIB) deposition, the high-pressure gas is allowed to expand in a vacuum, subsequently condensing into clusters. The clusters can be ionized and directed onto a surface, providing a highly anisotropic deposition.

Selectively etching as used herein includes but is not limited to patterning using one of lithography, photolithography, an extreme ultraviolet (EUV) lithography process, or any other known semiconductor patterning process followed by one or more etching processes. Various materials are referred to herein as being “removed” or “etched” whereas etching generally refers to one or more processes implementing the removal of one or more materials while leaving other protected areas of the materials that are masked during the lithography processes unaffected. Some examples of etching processes include but are not limited to the following processes, such as a dry etching process using a reactive ion etch (RIE) or ion beam etch (IBE), a wet chemical etch process, or a combination of these etching processes. A dry etch may be performed using a plasma. Ion milling, ion beam etching (IBE) sputter etching, or reactive ion etching (RIE) bombard the wafer with energetic ions of noble gases that approach the wafer approximately from one direction, and therefore, these processes are an anisotropic or a directional etching process.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition technique, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. Examples of various epitaxial growth techniques include, for example, rapid thermal chemical vapor deposition (RTCVD), low-energy plasma deposition (LEPD), ultra-high vacuum chemical vapor deposition (UHVCVD), low-pressure chemical vapor deposition (LPCVD), atmospheric pressure chemical vapor deposition (APCVD) and molecular beam epitaxy (MBE).

As known to one skilled in the art, doping of semiconductor materials (e.g., in channels, source/drains, substrates, etc.) is the intentional introduction of impurities into an intrinsic semiconductor for the purpose of modulating its electrical, optical, and structural properties. As used herein, “p-type” refers to the addition of impurities to an intrinsic semiconductor that creates deficiencies of valence electrons. In a silicon-containing semiconductor, examples of p-type dopants, i.e., impurities, include but are not limited to: boron, aluminum, gallium and indium. As used herein, “n-type” refers to the addition of impurities that contributes free electrons to an intrinsic semiconductor. In a silicon containing substrate, examples of n-type dopants, i.e., impurities, include but are not limited to antimony, arsenic, and phosphorous.

It should also be understood that material compounds will be described in terms of listed elements, e.g., SiGe. These compounds include different proportions of the elements within the compound, e.g., SiGe includes SixGe1-x where x is less than 1, etc. In addition, other elements can be included in the compound and still function in accordance with the present principles. The compounds with additional elements will be referred to herein as alloys.

As known by one skilled in the art, damascene processes for forming circuit lines and/or contacts typically include various steps of patterning of via holes and trenches in a dielectric material, such as an interlayer dielectric and filling the via holes and trenches with a layer of metal and planarizing the metal using a chemical mechanical process such as a chemical-mechanical polish (CMP) to remove overburden or excess metal.

Reference is now made to the figures. The figures provide schematic cross-sectional illustrations of semiconductor devices at intermediate stages of fabrication, according to one or more embodiments of the invention. The device provides schematic representations of the devices of the invention and are not to be considered accurate or limiting with regard to device element scale.

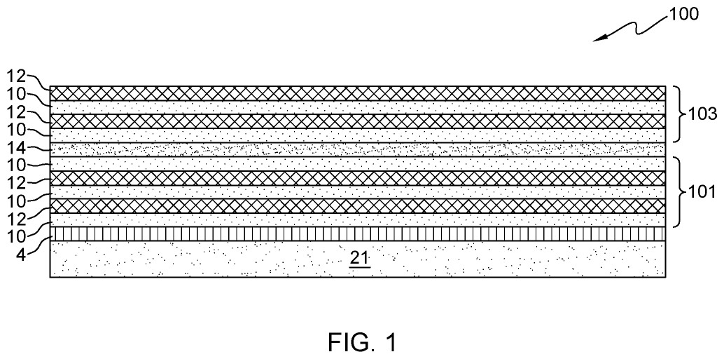

FIG. 1 depicts a cross-sectional view of semiconductor structure 100 after forming a nanosheet stack on semiconductor substrate 21, in accordance with an embodiment of the present invention. As depicted, FIG. 1 includes semiconductor substrate 21, sacrificial layer 4, sacrificial layer 14, and alternating layers of channel material 12 and sacrificial material 10. Semiconductor structure 100 is formed with known semiconductor processes for nanosheet stack formation.

Semiconductor substrate 21 may be, for example, a bulk substrate, which may be made from any of several known semiconductor materials such as, for example, silicon, germanium, silicon-germanium alloy, and compound (e.g., III-V and II-VI) semiconductor materials. Non-limiting examples of compound semiconductor materials include gallium arsenide, indium arsenide, indium phosphide, or indium gallium arsenide. Typically, semiconductor substrate 21 may be approximately but is not limited to, several hundred microns thick. In various embodiments, semiconductor substrate 21 is a wafer or a portion of a wafer. In some embodiments, semiconductor substrate 21 is composed of a semiconductor material that includes one or more of doped, undoped, or contains doped regions, undoped regions, stressed regions, or defect-rich regions. In some examples, semiconductor substrate 21 may include one or more other devices or transistors (not depicted). In an embodiment, semiconductor substrate 21 is one of a layered semiconductor substrate, such as a semiconductor-on-insulator substrate (SOI), germanium-on-insulator (GeOI), or silicon-on-replacement insulator (SRI). The nanosheet stack depicted in FIG. 1, includes a bottom layer of sacrificial material labeled as sacrificial layer 4 on semiconductor substrate 21. The nanosheet stack of FIG. 1 further includes alternating layers of sacrificial semiconductor material and semiconductor channel material and as known to one skilled in the art, the nanosheet stack depicted in FIG. 1 may include more or less layers of semiconductor channel material and the sacrificial materials. The nanosheet stack depicted in semiconductor structure 100 of FIG. 1 is composed of layers of sacrificial layer 4, sacrificial material 10, channel material 12, and sacrificial layer 14 where each nanosheet layer of the nanosheet stack can be formed with known epitaxial growth processes. Each nanosheet layer of the nanosheet stack may have a thickness ranging from about 3 nm to about 20 nm, although thinner or thicker nanosheets are also possible. Each of sacrificial layer 4, sacrificial layer 14, channel material 12, and sacrificial material 10 are grown or deposited by epitaxy and have a composition and an etch rate sensitivity that is different from semiconductor substrate 21.

Channel material 12 is composed of a semiconductor material. As previously discussed, channel material 12 may be grown or deposited by epitaxy using one of known processes such as UHVCVD, RTCVD, LEPVD, MBE, or another similar semiconductor material growth process. In various embodiments, channel material 12 is a silicon material. In other embodiments, channel material 12 is composed of any type IV semiconductor material or a compound (e.g., III-V or II-VI) semiconductor material. In various embodiments, channel material 12 is intrinsic or undoped. In some cases, using known doping methods, channel material 12 may be doped. Channel material 12 has a different etch sensitivity and/or etch rate than semiconductor substrate 21, sacrificial layer 4, sacrificial layer 14, and sacrificial material 10.

Sacrificial layer 4 and sacrificial layer 14 are composed of an epitaxially grown semiconductor material. For example, sacrificial layer 4 and sacrificial layer 14 can be formed using one of RTCVD, LEPD, LEPVD, MBE, or another known epitaxy growth process. In various embodiments, sacrificial layer 4 and sacrificial layer 14 are composed of silicon and germanium (SiGe). For example, sacrificial layer 4 and sacrificial layer 14 can be composed of SiGe with about sixty atomic percent germanium but is not limited to these percentages. The composition of sacrificial layer 4 and sacrificial layer 14 provides a different etch sensitivity than the etch sensitivity of sacrificial material 10, channel material 12, and semiconductor substrate 21. In some embodiments, sacrificial layer 4 and sacrificial layer 14 are composed of the same material. For example, sacrificial layer 4 and sacrificial layer 14 are composed of different materials.

Sacrificial material 10 is composed of a semiconductor material that can be deposited or grown using one of known epitaxy processes (e.g., RTCVD, LEPVD, etc.). In various embodiments, sacrificial material 10 is composed of SiGe. For example, sacrificial material 10 may have a germanium concentration less than 50 atomic percent or a germanium concentration ranging from about 20 atomic percent to about 40 atomic percent but is not limited to these materials and percentages. Sacrificial material 10 has a different etch sensitivity than sacrificial layer 4 and sacrificial layer 14. Sacrificial material 10 also has a different etch sensitivity than the material of semiconductor substrate 21.

In various embodiments, the nanosheet stack includes a bottom layer of sacrificial layer 4 on semiconductor substrate 21 that is covered by sacrificial material 10. As depicted, the nanosheet stack also includes a layer of channel material 12 that resides on sacrificial material 10. As depicted in FIG. 1, a second layer of sacrificial material 10 is over channel material 12 with a third layer of sacrificial material 10 over channel material 12. In FIG. 1, a third layer of sacrificial material 10 resides on the second layer of channel material 12 and is under a layer of sacrificial layer 14. The portion of the nanosheet stack composed of the bottom three layers of sacrificial material 10 and the bottom layers of channel material 12 is labeled as nanosheet stack portion 101. In later Figures., nanosheet stack portion 101 forms FET 201.

In FIG. 1, a layer of sacrificial material 10 resides on sacrificial layer 14 and two more layers of channel material 12 reside above sacrificial material 10 on sacrificial layer 14 with another layer of sacrificial material 10 between the two layers of channel material 12 as depicted in FIG. 1. In some cases, a top dielectric layer or hardmask (not depicted) may cover the top layer of channel material 12 in FIG. 1. As depicted in FIG. 1, the top two layers of sacrificial material 10 and the top two layers of channel material 12 are labeled as nanosheet stack portion 103. In later Figures, nanosheet stack portion 103 can form FET 203.

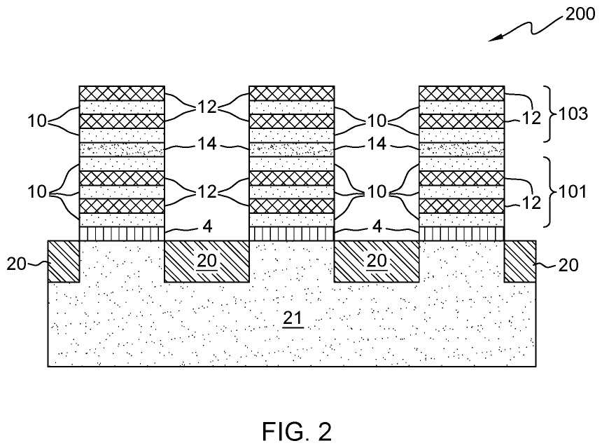

FIG. 2 depicts a cross-sectional view of semiconductor structure 200 after patterning the nanosheet stack and forming STI 20, in accordance with an embodiment of the present invention. As depicted, FIG. 2 includes the elements of FIG. 1 with portions of STI 20 formed under the removed portions of the nanosheet stack. Using known photolithography and etching processes (e.g., RIE), portions of the nanosheet stack composed of sacrificial layer 4, sacrificial material 10, channel material 10, and sacrificial layer 14 are selectively removed and a top portion of semiconductor substrate 21 under the removed portions of the nanosheet stack is also removed. Using known deposition processes, STI 20 are formed in semiconductor substrate 21 adjacent to each remaining portion of nanosheet stack portion 101. Each of STI 20 is adjacent to and below a remaining portion of sacrificial layer 4 in FIG. 2. In various embodiments, the horizontal width of each of STI 20 is 30 to 100 nm. In some cases, the width of STI 20 may be greater or less than 30 to 100 nm.

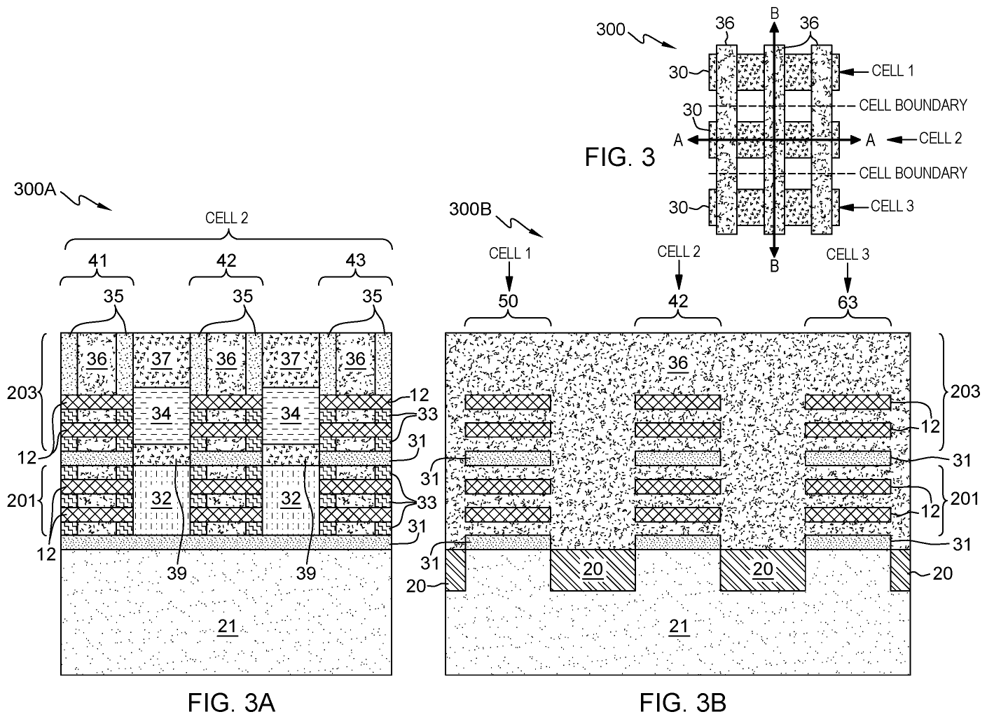

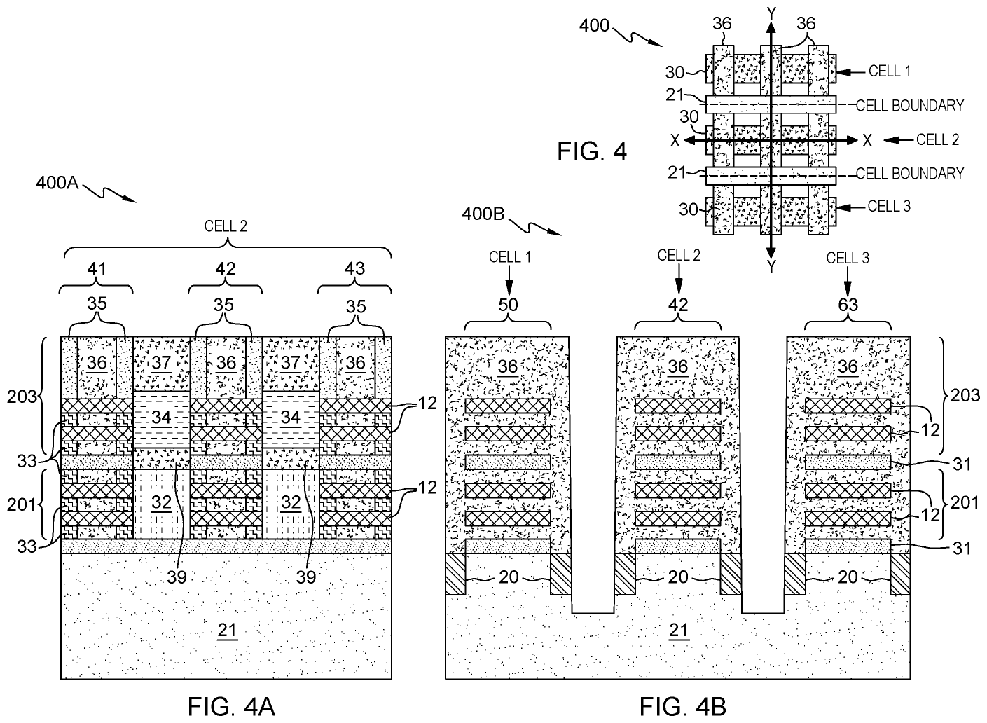

FIG. 3 depicts a top view 300 of semiconductor structures 300A and 300B after forming CFET 41, CFET 42, and CFET 43 as depicted in FIG. 3A and CFET 50, CFET 42, and CFET 63 in FIG. 3B, in accordance with an embodiment of the present invention. As depicted, FIG. 3 includes a top view of cell 1, cell 2, cell 3, active area 30, gate 36, with a dotted line representing a lower cell boundary between cell 1 and cell 2 and an upper cell boundary between cell 2 and cell 3. Also, included in FIG. 3 is the identification of sections X-X and Y-Y for cross-sections A and B of FIGS. 3A, 3B, 4A, 4B. 5A, 5B, 6A, 6B, 7A, 7B, 8A and 8B later. Cross-sections X-X, as depicted, are parallel to and through one of active area 30 that is to the longitudinal direction of the gates 36. Therefore, FIGS. 3A, 4A, 5A, 6A, 7A, and 8A depicted later are cross-sections X-X that are perpendicular to each of gate 36 as are shown by the location of cross-section X-X. Cross-sections Y-Y are parallel to the longitudinal direction of gates 36 and through one of gate 36. FIGS. 3B, 4B, 5B, 6B, 7B and 8B depicted later each depict cross-sections Y-Y that are parallel to and through one of gate 36.

In various embodiments, gate 36 is a replacement metal gate structure (e.g., includes a high-k gate dielectric layer, a gate electrode, inner spacers, gate spacer, associated liners, and any other replacement metal gate elements not depicted in FIG. 3).

FIG. 3A depicts a cross-sectional view in the X-X direction depicted in FIG. 3 of semiconductor structure 300A after forming CFET 41, CFET 42, CFET 43, CFET 50, CFET 63 in cells 1, 2, and 3 inner spacers 33, in accordance with an embodiment of the present invention. As depicted, FIG. 3A includes cell 2 with ILD 37, ILD 39, gate 36, gate spacer 35, channel material 12, inner spacers 33, dielectric isolation material 31, top S/D 34, bottom S/D 32, FET 201. FET 203 in each of CFET 41, CFET 42, and CFET 43 that are on a bottom layer of dielectric isolation material 31 above semiconductor substrate 21. As known to one skilled in the art, a cell can be composed of more than one or many CFET devices.

Three FET 203 are each above one of the three FET 201 where each pair of vertically stacked FET 201 and FET 203 form one of CFET 41, CFET 42, and CFET 43 in cell 2, as depicted in FIG. 3A. In FIG. 3A, each nanosheet stack portion 101 and nanosheet stack portion 103 depicted in FIG. 2 are each formed into FET 201 and FET 203, respectively to create CFET 41, CFET 42, and CFET 43 in cell 2.

FET 201 and FET 203 are formed using known semiconductor processes for nanosheet FET formation of GAA FETs with a replacement metal gate. CFET 41, CFET 42, and CFET 43 are formed using known methods of forming stacked nanosheet FETs with a GAA structure. As depicted in FIG. 3A, the three bottom FETs of each of CFET 41, CFET 42, and CFET 43 are labeled FET 201. Each of FET 201 can be formed on a bottom layer of dielectric isolation material 31 using nanosheet stack portion 101 (depicted in FIG. 1 and FIG. 2). Each of FET 201 are formed from a remaining portion of nanosheet stack portion 101 that includes a portion of the lower two layers of channel material 12, bottom S/D 32, gate 36 with gate spacer 35, and inner spacers 33 as depicted in FIG. 3A. Each FET 201 resides on dielectric isolation material 31 and the top surface of bottom S/D 32 is covered by ILD 39. As depicted in FIG. 3A, the sidewalls of channel material 10 of FET 201 are surrounded by bottom S/D 32.

As depicted in FIG. 3A, each of FET 203 can be formed on dielectric isolation material 31 above FET 201 using nanosheet stack portion 103 (depicted in FIG. 1 and FIG. 2). Each of FET 203 includes a portion of the upper two layers of channel material 12, top S/D 34, gate 36 with gate spacer 35, and inner spacers 33 as depicted in FIG. 3A. Each FET 203 resides on dielectric isolation material 31 (e.g., a middle isolation layer) that is on FET 201. Each top S/D 34 is covered by ILD 37. As depicted in FIG. 3A, the sidewalls of channel material 10 of FET 203 are surrounded by top S/D 34.

The method to form semiconductor structure 300A from semiconductor structure 200 is a known method of forming stacked GAA FETs from nanosheet stacks and includes using nanosheet stack portion 101 and nanosheet stack portion 103 depicted in FIG. 2 to form FET 201 and FET 203, respectively.

In various embodiments, the steps to transform nanosheet stack portion 101 depicted in FIG. 2 into FET 201 and nanosheet stack portion 103 depicted in FIG. 2 into FET 203 are discussed below. As known to one skilled in the art, in some cases, the order of the steps discussed below, and the processes may be different in other examples of a method to form semiconductor structure 300A.

For example, a dummy gate with a hardmask (not depicted) may be formed on the top layer of channel material 12 of nanosheet stack portion 101 (depicted in FIG. 2) and around both of nanosheet stack portion 101 and nanosheet stack portion 103 (both nanosheet stacks 101 and 103 are depicted in FIG. 2) using known dummy formation processes.

Sacrificial layer 4 and sacrificial layer 14 depicted in FIG. 2 can be selectively removed, for example, using a wet or dry lateral etching process such as a vapor phase HCl dry etch. A conformal deposition process such as ALD can deposit dielectric isolation material 31 in the recesses left by the removal of sacrificial layer 4 and sacrificial layer 14. The portion of dielectric isolation material 31 on semiconductor substrate 21 can be a bottom dielectric isolation (BDI) for FET 201 and dielectric isolation material 31 above FET 201 can be a middle isolation layer (MDI) separating FET 201 and FET 203. Dielectric isolation material 31 may be composed of any suitable dielectric material such as any dielectric material such as silicon nitride (SiN), silicon boron carbon nitride (SiBCN), silicon oxide carbon nitride (SiOCN), aluminum oxide (AlOx), and may include a single layer or may include multiple layers of dielectric material. Dielectric isolation material 31 may have a thickness ranging from about 3 nm to about 15 nm. A directional etch process such as RIE removes exposed horizontal portions of dielectric isolation material 31.

In various embodiments, inner spacers 33 are formed by recessing the outer edges of sacrificial material 10 depicted in FIG. 2 (e.g., using one or more known lateral etching processes) followed by a conformal deposition of a dielectric material such as silicon oxide, silicon oxynitride, silicon nitride, SiBCN, SiOC, low-k dielectric or any combination of these materials for inner spacers 33. A directional etching process removes the exposed horizontal portions of inner spacers 33.

In various embodiments, bottom S/D 32 may be epitaxially grown from exposed portions of channel material 10 in nanosheet stack portion 101 (depicted in FIG. 2). Bottom S/D 32, as depicted, surrounds a vertical portion of FET 201 on the bottom dielectric isolation material 31. Bottom S/D 32 may surround the exposed sidewalls of the lower layers of inner spacers 33 and channel material 12 in FET 201. During the epitaxial growth of bottom S/D 32, the sidewalls of nanosheet stack portion 103 depicted in FIG. 2 may be protected by a sacrificial layer, or in other cases, any epitaxial growth on the sidewall of nanosheet stack portion 103 may be removed, for example, by a dry etch process. In some embodiments, after bottom S/D 32 growth, a dry or wet etching process recesses bottom S/D 32 to a level approximately even with the bottom surface of the middle layer of dielectric isolation material 31. In other cases, the top surface of S/D 32 is just above the top surface of the second layer of channel material 12.

In some embodiments, bottom S/D 32 is doped. For example, bottom S/D 32 is doped with boron, phosphorous, or another semiconductor doping material. The dopant used will depend on the type of FET 201 being formed (e.g., whether a PFET or an NFET is desired for FET 201). In various embodiments of the present invention, one or both of bottom S/D 32 and top S/D 34, formed later, may be doped in situ by adding one or more dopant species to the epitaxial source/drain material.

In some examples, a combination of dry and wet etch and recessing steps on bottom S/D 32 may recess bottom S/D 32, for example, to a level where the top surface of S/D 32 may be level with any portion of dielectric isolation material 31 above FET 201.

ILD 39 may be deposited, for example, by ALD, CVD, PVD, etc. on the exposed top surface of bottom S/D 32. ILD 39 may be composed of any dielectric material used in nanosheet semiconductor devices (e.g., SiN, SiBCN, SiO₂, etc.). As depicted, ILD 39 resides on top S/D 32 between two facing portions of dielectric isolation material 31 in FET 201. A CMP can planarize ILD 39 and ILD 39 recessed, for example, by RIE, to a level approximately even with dielectric isolation material 31 on FET 201.

In various embodiments, top S/D 34 is epitaxially grown surrounding the sidewall of channel material 12 in nanosheet stack portion 103 depicted in FIG. 2. As depicted in FIG. 3A, top S/D 34 surrounds the portions of the two upper layers of channel material 12 and inner spacers 33 in FET 203. In some cases, top S/D 34 may be doped, for example, with an n-type dopant or a p-type dopant. As depicted in FIG. 3A, top S/D 34 resides on ILD 39. In some examples, the top surface of top S/D 34 may be equal to or higher than the top surface of the uppermost layer of channel material 12. ILD 37 may be deposited on top S/D 34.

Gate 36 may be formed using known processes for removing the dummy gate and forming a metal replacement gate for gate 36 with gate spacer 35. In various embodiments, using known replacement metal gate processes, gate 36 can be formed (e.g., depositing a gate dielectric, depositing a gate metal, conformally depositing a dielectric spacer material, and performing an RIE to remove horizontal portions of the spacer material). As previously discussed, gate 36 may be a metal replacement gate with a high-k gate dielectric layer. After forming gate 36 with gate spacer 35, a CMP may planarize the top surface of semiconductor structure 300A.

In various embodiments, each of FET 201 and FET 203 is either a PFET or an NFET. As depicted in FIGS. 3A and 3B, FET 201 and FET 203 are gate-all-around FETs and the combination of one of FET 203 stacked above one of FET 201 each forms one of CFET 41, CFET 42, and CFET 43. In various embodiments, each CFET of CFET 41, CFET 42, and CFET 43 is composed of two different complementary types of FET 201 and FET 203 (e.g., FET 201 is a PFET and FET 203 is an NFET or FET 201 is an NFET and FET 203 is a PFET). In an embodiment, each of CFET 41, CFET 42, and CFET 43 are a stacked CMOS device with the same type of FETs (e.g., both FET 201 and FET 203 are PFETs). While only two FETs (i.e., FET 201 and FET 203 are stacked in FIG. 3A), in other examples, more than two FETs may be stacked to form CFET 41, CFET 42, and CFET 43 (e.g., CFET 41 may have two NFETs and two PFETs).

FIG. 3B depicts a cross-sectional view in the Y-Y direction depicted in FIG. 3 of semiconductor structure 300B after forming CFET 50, CFET 42, and CFET 63 in cell 1, cell 2, and cell 3, respectively. As depicted, FIG. 3B includes three of FET 201 each under dielectric isolation material 31 and under one of FET 203 where each pair of stacked FET 201 and FET 203 form one of CFET 50, CFET 42, and CFET 6 on a bottom layer of dielectric isolation material 31 and adjacent to STI 20 in semiconductor substrate 21. CFET 50, CFET 42, and CFET 63 are formed with the processes discussed above in detail with respect to FIG. 3A. As depicted, each STI 20 is covered by a portion of gate 36 and resides in semiconductor substrate 21 between two of CFET 50, CFET 42, and CFET 63.

FIG. 4 depicts a top view 400 of the semiconductor structure of FIGS. 4A and 4B after forming gate cuts exposing a portion of semiconductor substrate 21, in accordance with an embodiment of the present invention. As depicted, FIG. 4 includes the elements of FIG. 3 with each gate cut in each cell boundary where each gate cut exposes a portion of semiconductor substrate 21. FIG. 4 depicts two gate cuts exposing two portions of semiconductor substrate 21. The gate cuts are perpendicular to each of gate 36 and are parallel to cross-section X-X as labeled in FIG. 4. The two gate cuts are parallel to active area 30 as depicted in FIG. 4.

FIG. 4A depicts a cross-sectional view of semiconductor substrate 400A in the X-X direction depicted in FIG. 4 of cell 2 after forming the gate cuts (not depicted in FIG. 4A), in accordance with an embodiment of the present invention. As depicted, FIG. 4A includes the elements of FIG. 3A. FIG. 4A depicts semiconductor substrate 21, dielectric isolation material 31, CFET 41, CFET 42, and CFET 43 in cell 2 with FET 201 and FET 203, gates 36, inner spacers 33, gate spacer 35, channel material 12, top S/D 34 under ILD 37, and bottom S/D 32 under ILD 39. Because of the location of cross-section X-X as depicted in FIG. 4, the gate cuts are not illustrated in FIG. 4A.

FIG. 4B depicts a cross-sectional view in the Y-Y direction of semiconductor structure 400B after forming two gate cuts in each of gate 36, in accordance with an embodiment of the present invention. As depicted, FIG. 4B includes CFET 50, CFET 42, and CFET 63 with a first gate cut between CFET 50 in cell 1 and CFET 42 in cell 2 and a second gate cut between CFET 42 in cell 2 and CFET 63 in cell 3. In FIG. 4B, the first portion of gate 36 is removed by the leftmost gate cut that is between CFET 50 and CFET 42. The second portion of gate 36 that is removed by the rightmost gate cut is between CFET 42 and CFET 63. In FIG. 4A, each gate cut extends down through a portion of gate 36, through one of STI 20, and into a top portion of semiconductor substrate 21.

The gate cuts occur after forming gate 36 (i.e., after forming gate 36 as a replacement metal gate). In various embodiments, the gate cut trenches are formed by conventional lithography and etching process. The width of the gate cut should leave sufficient amounts of gate 36 to prevent a reduction of the electrical performance of each of the stacked FETs formed with nanosheet stack portion 101 and nanosheet stack portion 103. For example, a horizontal distance from the sidewall of the gate cut and the sidewall of each channel material 10 should be in the range of at least 10 nm to 15 nm but is not limited to this range. The width of the gate cut is dependent, at least in part, on the horizontal space between adjacent FET 201 and FET 203. In general, the denser or more closely packed adjacent FET 201 and FET 203 are, then, the thinner the gate cut. In other words, with increasing CFET density, the width of the gate cuts is reduced. A typical width of the gate cut between adjacent CFETs can be 10 nm to 50 nm but is not limited to this width as the width is dependent, at least in part, on the space between adjacent CFETs (e.g., CFET 50, CFET 42, and CFET 63).

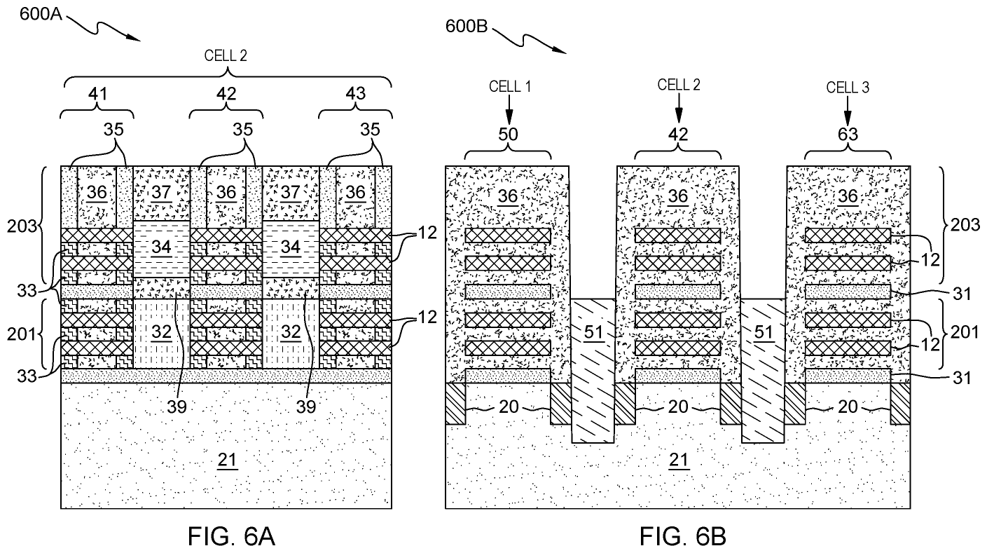

As depicted in FIG. 4B, the depth of the two gate cuts extends beyond STI 20 and into semiconductor substrate 21. For example, the gate cut may be level with the surface of semiconductor substrate 21 or may extend up to 100 nm below the surface of semiconductor substrate 21 but is not limited to these depths. In other examples, the depth of the gate cut should be from the top surface of semiconductor structure 400B to at least the top surface of dielectric isolation material 31 on semiconductor substrate 21. In some cases, the depth of the gate cuts may extend even further into semiconductor substrate 21. For example, a deeper gate cut into semiconductor substrate 21 may provide further stress advantages after depositing dielectric materials into the gate cut as occurs in later process steps depicted in FIGS. 6A-8B. In various embodiments, the gate cuts occur in gate 36 above and through STI 20 and are between each of the adjacent CFET devices. As depicted, the gate cuts leave a portion of gate 36 around the sidewall of each of channel material 12 in FET 201 and FET 203.

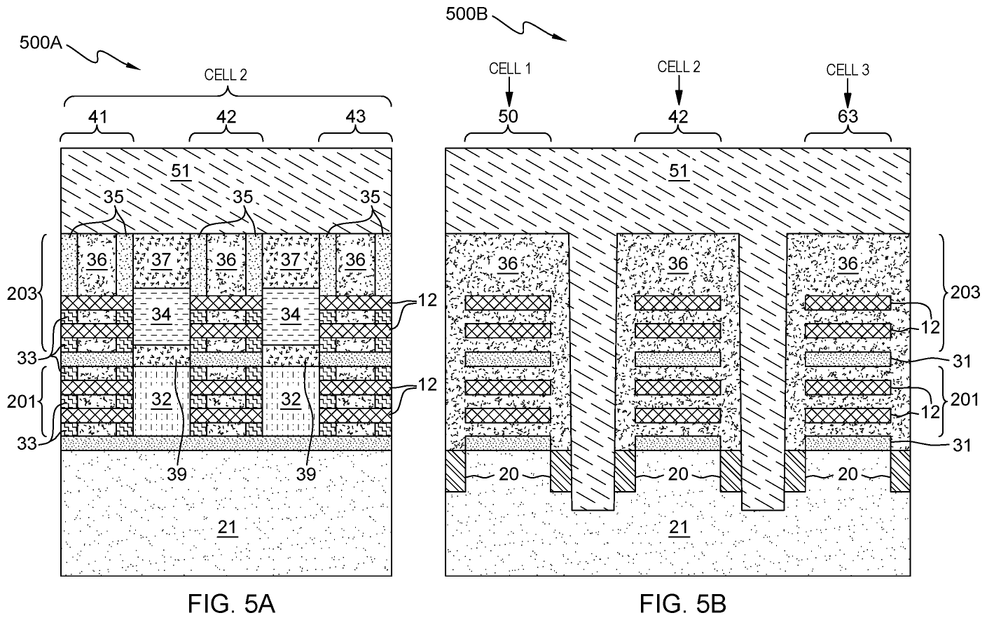

FIG. 5A depicts a cross-sectional view in the X-X direction of semiconductor structure 500A after depositing first dielectric stressor material 51, in accordance with an embodiment of the present invention. As depicted, FIG. 5A includes the elements of FIG. 4A and first dielectric stressor material 51. Using one or more known deposition process such as but not limited to ALD, CVD, PVD. MLD, or spin-on techniques, a layer of first dielectric stressor material 51 is deposited over semiconductor structure 500A followed by a planarization process, such as CMP. As depicted in the cross-section view X-X in FIG. 5A, first dielectric stressor material 51 is on the top surface of ILD 37, gate 36, and gate spacer 35.

The specific dielectric material selected for first dielectric stressor material 51 can be determined based on the type of FET (e.g., a PFET or an NFET) is formed for FET 201. As known to one skilled in the art, some dielectric materials are capable of applying a lateral stress on the sidewall of adjacent materials. For example, when dielectric stressor material 51 is deposited in a gate cut (not depicted in FIG. 5A) between two adjacent FET 201, dielectric material 51 can be selected to provide one of a compressive stress or a tensile stress on channel material 12 of FET 201. In various embodiments, the first dielectric stressor material 51 may include one or more layers. For example, first dielectric stressor material 51 may be composed of any dielectric material such as silicon oxide, silicon oxynitride, silicon nitride, SiBCN, SiOC, another low-k dielectric materials, or any combination of these materials.

FIG. 5B depicts a cross-sectional view in the Y-Y direction of semiconductor structure 500B after depositing the first dielectric stressor material 51, in accordance with an embodiment of the present invention. As depicted, FIG. 5B includes the elements of FIG. 4B and first dielectric stressor material 51. Using one or more of the deposition processes previously discussed with respect to FIG. 5A, first dielectric stressor material 51 is deposited over and around the exposed surfaces of gate 36, STI 20, and a top portion of semiconductor substrate 21. As depicted, first dielectric stressor material 51 covers the top surface of gate 36 and fills the leftmost gate cut in gate 36 which is between CFET 50 and CFET 42 and the rightmost gate cut which is between CFET 42 and CFET 63. As depicted in FIG. 5B, the leftmost gate cut separates cell 1 from cell 2 and therefore, separates the CFETs in cell 1 such as CFET 50 from the CFETs in cell 2 such as CFET 42. Similarly, the rightmost gate cut separates cell 2 CFET devices (e.g., CFET 42) from the CFETs in cell 3 (e.g., CFET 63). First dielectric stressor material 51, in FIG. 5B, fills both depicted gate cuts and first dielectric stressor material 51 abuts the sidewalls of each of FET 201 and FET 203 (e.g., directly abuts gate 36 of each of FET 201 and FET 203) as well as covering the top surface of gate 36.

FIG. 6A depicts a cross-sectional view in the X-X direction of semiconductor structure 600A after performing a CMP and recessing first dielectric stressor material 51 in each gate cut, in accordance with an embodiment of the present invention. As depicted, FIG. 6A includes the elements of FIG. 5A without first dielectric stressor material 51. The CMP planarizes the top surfaces of semiconductor structure 600A and removes first dielectric stressor material 51 from the top surface of semiconductor structure 600A. The recessing of first dielectric stressor material 51 in each gate cut is not depicted in FIG. 6A. In semiconductor structure 600A, the top surfaces of gate 36 and gate spacer 35 are exposed.

FIG. 6B depicts a cross-sectional view in the Y-Y direction of semiconductor structure 600B after performing the CMP and recessing first dielectric material 51 in each gate cut, in accordance with an embodiment of the present invention. As depicted, FIG. 600B includes the elements of FIG. 5B without first dielectric stressor material 51 on the top surface of gate 36 and without the top portion of first dielectric stressor material 51 in each gate cut adjacent to FET 203.

In various embodiments, a CMP removes the portion of first dielectric stressor material 51 above gate 36. After the CMP, using one or more known wet or dry etching processes such as but not limited to RIE, the top portion of first dielectric stressor material 51 in each of the gate cuts is removed. The two gate cuts, as depicted and previously discussed, are on either side of CFET 42 in cell 2. After recessing first dielectric stressor material 51 in the two gate cuts, the top surface of first dielectric stressor material 51 level with a portion of the sidewall of dielectric isolation material 31 that is between FET 201 and FET 203. As depicted, the remaining portion of first dielectric stressor material 51 abuts each of two adjacent FET 201. In various embodiments, the top surface of the remaining first dielectric stressor material 51 is at least level with or above the top layer of channel material 12 in FET 201. However, in other cases, the remaining amount of first dielectric stressor material 51 after recessing extends approximately to the height of the top surface of the middle layer of dielectric isolation material 31 so that first dielectric material 51 applies a stress to channel material 12 through the sidewall of gate 36 in FET 201.

In various embodiments, when FET 201 is a PFET, then the dielectric material selected for first dielectric material 51 generates a compressive stress on channel material 12 through gate 36 of FET 201 and therefore, improves the electrical performance of FET 201 (e.g., improves hole mobility in the channels of FET 201 as a PFET). In other embodiments, where FET 201 is an NFET, then first dielectric stressor material 51 is selected to create a tensile stress on FET 201. The tensile stress applied to channel material 12 in FET 201 improves electron mobility in the channels of FET 201 as an NFET.

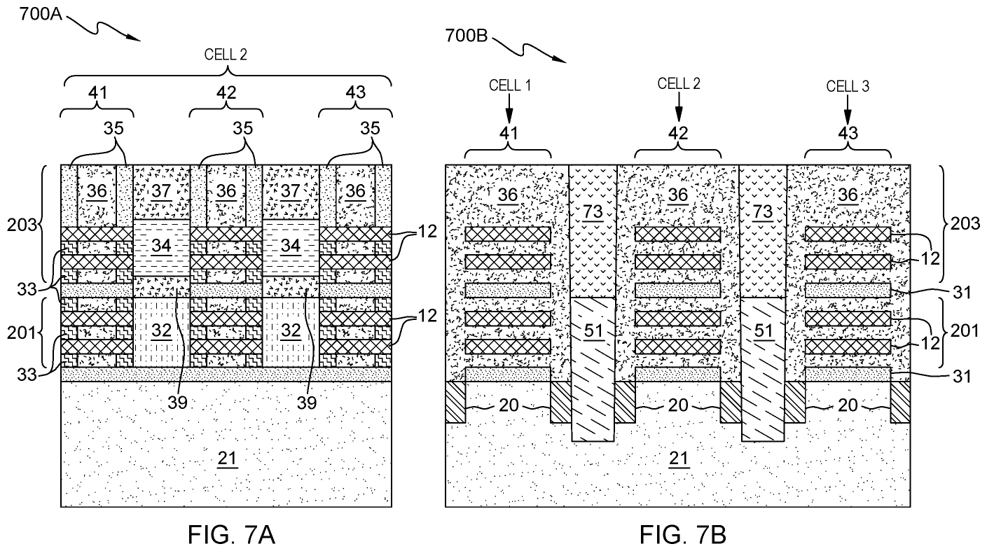

FIG. 7A depicts a cross-sectional view in the X-X direction of semiconductor structure 700A after depositing second dielectric stressor material 73 and performing a CMP, in accordance with an embodiment of the present invention. As depicted, FIG. 7A includes the elements of FIG. 6A in cell 2. Second dielectric stressor material 73 and first dielectric stressor material 51 are not depicted in cross-section X-X. After the CMP, second dielectric stressor material 73 is removed from the top surface of semiconductor structure 700A and the top surfaces of gate 36 and gate spacer 35 are exposed.

The specific dielectric material selected for second dielectric stressor material 73 (not depicted in FIG. 7A) can be determined based on the type of FET that is formed for FET 203 (e.g., a dielectric material generating a compressive stress for a PFET or material generating a tensile stress on an NFET). Second dielectric stressor material 73 may be deposited with one or more of the processes discussed with respect to first dielectric stressor material 51 in the description of FIG. 5A.

FIG. 7B depicts a cross-sectional view in the Y-Y direction of semiconductor structure 700B after depositing second dielectric stressor material 73 and performing the CMP, in accordance with an embodiment of the present invention. As depicted, FIG. 7B includes the elements of FIG. 6B but with a portion of second dielectric stressor material 73 above first dielectric stressor material 51 in the gate cut. For example, FIG. 7B depicts second dielectric stressor material 73, first dielectric material 51, gate 36, gate spacer 35, inner spacers 33, channel material 12, bottom S/D 32, top S/D 34, dielectric isolation material 31, FET 201 and FET 203 forming CFET 50, CFET 42, and CFET 63. As depicted, second dielectric stressor material 73 fills the leftmost gate cut between FET 203 in cell 1 and FET 203 in cell 2 and fills the rightmost gate cut between FET 203 in cell 2 and FET 203 in cell 3.

As discussed above, second dielectric stressor material 73 may be deposited with one or more of the processes and material discussed with respect to first dielectric stressor material 51 in the description of FIG. 5A. The specific dielectric material selected for second dielectric stressor material 73 can be determined based on the type of FET (e.g., a PFET or an NFET) that is formed for FET 203. In embodiments where FET 203 is a PFET, second dielectric stressor material 73 is selected with a dielectric material composition and/or a material that creates a compressive stress on channel material 12 of FET 203. Similarly, when FET 203 is an NFET, second dielectric material 73 is selected to provide a tensile stress on channel material 12 of FET 203.

As depicted in FIG. 7B, the top surface of second dielectric stressor material 73 is level with the top surface of gate 36 after the CMP. The bottom surface of second dielectric stressor material 73 in FIG. 7B resides on the top surface of first dielectric stressor material 51. Second dielectric stressor 71 resides between two adjacent FET 203. In various embodiments, the bottom surface of second dielectric stressor material 73 is level or approximately level with dielectric isolation material 31. In various embodiments, second dielectric stressor material 73 abuts or directly contacts a sidewall of gate 36 of each of the two adjacent FET 203. As depicted, each of the two adjacent FET 203 are separated by the top portion of the gate cut that is filled with second dielectric stressor material 73. The portion of gate 36 contacting second dielectric stressor material 73 can be the portion of gate 36 that is in direct contact with the sidewall of the two layers of channel material 12 in FET 203.

As previously discussed, when FET 203 is a PFET, the material selected for second dielectric stressor material 73 produces a compressive stress on the portions of gate 36 surrounding the upper part of the filled gate cut that is adjacent to FET 203. Second dielectric stressor material 73 produces a compressive stress on gate 36 and the adjacent channel material 12 in FET 203. For example, when FET 203 is a PFET, second dielectric stressor material 73 is a material such as but not limited to a nitride that creates a compressive stress on channel material 12. As previously discussed, a compressive stress on channel material 12 of a PFET creates a higher hole mobility in channel material 12 and can improve PFET electrical performance.

However, in other examples when FET 203 is an NFET, the material selected for second dielectric stressor material 73 produces a tensile stress on the portions of gate 36 surrounding the upper part of the filled gate cut adjacent to FET 203. In this case, second dielectric stressor material 73 produces a tensile stress on the adjacent channel material 12 in FET 203 where the tensile stress increases the electron mobility of the NFET (i.e., FET 203).

As previously discussed, FET 201 and FET 203 can each be either a NFET or a PFET in an NFET/PFET pair of the CFET device. For example, when FET 201 is a PFET in one of CFET 41, 42, or 43, then FET 203 is PFET (i.e., FET 203 is a complementary type FET to FET 201 under FET 203). In various embodiments, when FET 203 is a PFET, second dielectric stressor material 73 is selected to apply a compressive stress on channel material 12 in FET 203 and then, FET 201 is an NFET. As previously discussed, when FET 201 is an NFET, then first dielectric stressor material 51 applies a tensile stress on channel material 12 in FET 201 to improve NFET electrical performance, and second dielectric stressor material 73 applies a compressive stress to improve PFET electrical performance.

In an embodiment, in stacked complementary metal-oxide semiconductor (CMOS) devices, when FET 203 and FET 201 are both PFETs or are both NFETs, only first dielectric stressor material 51 is deposited to provide the appropriate stress (e.g., a compressive stress if both FET 201 and FET 203 are PFETs in a stacked CMOS device).

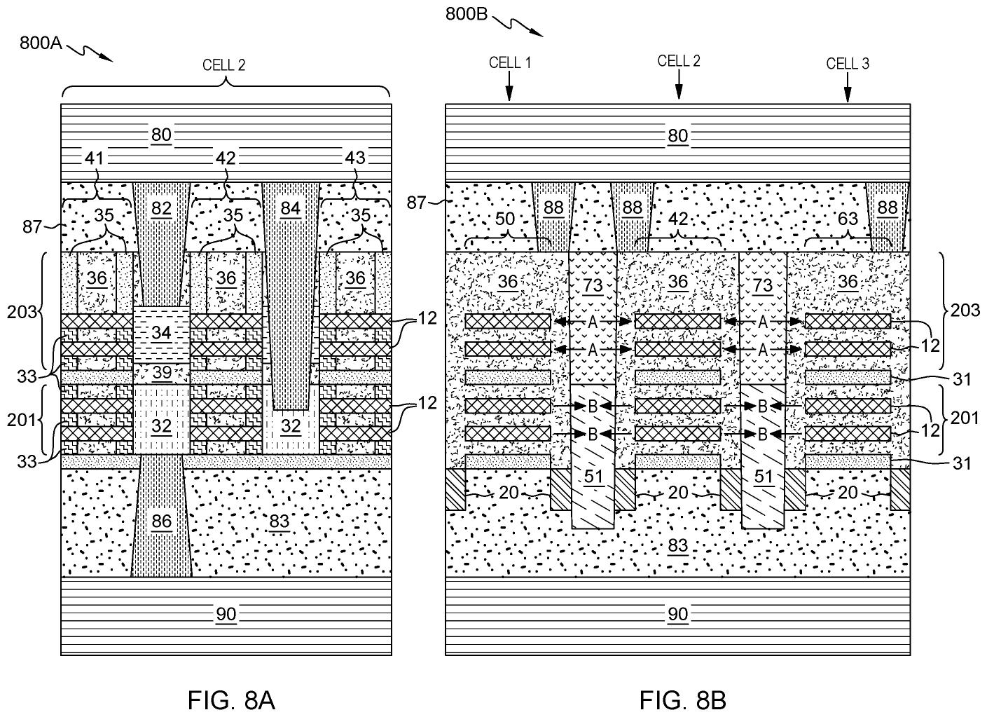

FIG. 8A depicts a cross-sectional view in the X-X direction of semiconductor structure 800A through cell 2 after depositing ILD 87, forming top contact 82, top contact 84, gate contacts 88 (not depicted in FIG. 8A), forming frontside interconnect layers 80, performing carrier wafer bonding, semiconductor substrate 21 removal, depositing a backside ILD 83, forming backside contact 86, and forming backside interconnect layers 90, in accordance with an embodiment of the present invention. As depicted, FIG. 8A includes all of the elements of FIG. 7A and ILD 87, top contact 82, top contact 84, top interconnect layers 80, ILD 83, bottom contact 86, and bottom interconnect layers 90. For example, semiconductor structure 800A depicts CFET 41 and CFET 42 which include bottom S/D 32 below top S/D 34 where top contact 82 connects to top interconnect layers 80, top S/D 34 between CFET 42 and CFET 43 connects to top interconnect layers 80, and bottom contact 86 under bottom S/D 32 between CFET 42 and CFET 43 connects to bottom interconnect layers 90. Top contact 82 passes through a portion of ILD 87 and ILD 37 to contact top S/D 34 between two adjacent FET 203 in CFET 41 and CFET 42. Top contact 84 passes through ILD 87, ILD 37, top S/D 32, and ILD 39 to connect to bottom S/D 34 which is between two adjacent FET 201 in CFET 42 and CFET 43. As depicted, each of CFET 41, CFET 42, and CFET 43 reside in cell 2.

Semiconductor structure 800A may be formed from semiconductor structure 700A using known back end of line contact formation processes and interconnect layer formation processes. For example, ILD 87 can be deposited on the top surfaces of gate 36 and gate spacer 35 followed by top contact 82, top contact 84 formation, and gate contacts 88 (not depicted in FIG. 8A). Top interconnect layers 80 can be formed over ILD 87 and top contact 82 and top contact 84.

Using known semiconductor processes, a carrier wafer may be bonded to top interconnect layers 80 and the wafer flipped so that semiconductor substrate 21 may be removed (e.g., by wafer grinding and/or wet etching processes) to expose the bottom layer of dielectric isolation material 31. ILD 83 can be deposited over dielectric isolation material 31. Back contact 86 can be formed, for example, using known damascene processes. Bottom interconnect layers 90 can be formed on ILD 83 and back contact 86.

FIG. 8B depicts a cross-sectional view in the Y-Y direction of semiconductor structure 800B after depositing ILD 87, forming top contact 82 and top contact 84 (not depicted in FIG. 8B), forming gate contacts 88, forming frontside interconnect layers 80, performing carrier wafer bonding, semiconductor substrate 21 removal, depositing a backside ILD 83, forming backside contact 86, and forming backside interconnect layers 90, in accordance with an embodiment of the present invention. As depicted, FIG. 8B includes all of the elements of FIG. 7B and ILD 87, gate contacts 88, top interconnect layers 80, ILD 83, and bottom interconnect layers 90. Semiconductor structure 800B can be formed using the processes discussed above with respect to FIG. 8A. Also, included in FIG. 8B are arrows A and arrows B indicating the direction of the stresses applied by first dielectric stressor material 51 and second dielectric stressor material 73.

Gate contacts 88 connect each of gate 36 through ILD 87 to top interconnect layers 80. Three gate contacts 88 are depicted in FIG. 8B where each of gate contacts 88 connect one of gate 36 on CFET 50 in cell 1, CFET 42 in cell 2, and CFET 6 in cell 3 to top interconnect layers 80. As depicted, FIG. 8B depicts the two filled gate cuts where the first gate cut is between cell 1 and cell 2 (i.e., the gate cut between CFET 50 and CFET 42) and the second gate cut is between cell 2 and cell 3 (i.e., the gate cut between CFET 42 and CFET 63). The bottom portion of each gate is filled with first dielectric stressor material 51 that is under second dielectric stressor material 73. ILD 87 covers the top surface of second dielectric stressor material 72.

In various embodiments, when FET 201 is a PFET, then the dielectric material selected for first dielectric material 51 generates a compressive stress depicted by arrows A on channel material 12 through gate 36 of FET 201 and therefore, first dielectric stressor material 51 improves the electrical performance of FET 201 by improving hole mobility in the channels of FET 201 (i.e., a PFET). As depicted in FIG. 8B, when FET 201 is a PFET, then FET 203 is an NFET and second dielectric stressor material 73 generates a tensile stress to improve the electron mobility of the channels of the NFET. The tensile stress is depicted by arrows B on channel material 12 of FET 203.

In other embodiments, when FET 201 is an NFET and FET 203 is a PFET, then first dielectric stressor material 51 is selected to create a tensile stress (not depicted in FIG. 8B) on FET 201 and second dielectric stressor material 73 generates a compressive stress. The tensile stress applied to channel material 12 in FET 201 by first dielectric stressor material 51 improves electron mobility in the channels of an NFET for FET 201 while the compressive stress improves hole mobility to improve the electrical performance of FET 203 (PFET).

In various embodiments, semiconductor structure 800B with two different dielectric materials filling each gate cut between two adjacent CFET devices (e.g., a gate cut between CFET 41 and CFET 42) provides an optimized or improved electrical performance for each of the NFET and the PFET in the CFET device by selecting one dielectric material between adjacent PFETs to provide a compressive force on the PFET channels and a second dielectric material between adjacent NFETs to provide a tensile force on the NFET channels. As depicted, semiconductor structure 800B with arrows A in FET 203 when FET 203 is a PFET and arrows B in FET 201 and with FET 201 as an NFET includes second dielectric stressor material 73 producing tensile stress to channel material 12 of FET 203 (e.g., NFET) and second dielectric material 73 producing compressive stress indicated by arrows A to channel material 12 of FET 203 (e.g., PFET). As a result, the electrical performance of both FET 201 and FET 203 is enhanced by increasing electron mobility in FET 201 (e.g., NFET) and increasing hole mobility in FET 203 (e.g., PFET) caused by the additional tensile stresses on channel material 12 provided by second dielectric stressor material 73 in the upper portion of a gate cut and first dielectric material 51 in the lower portion of the gate cut, respectively. This novel semiconductor structure 800B improves CFET device electrical performance by introducing the preferred type of stress to the channels of the PFETs and the channels of the NFET in the CFET device.

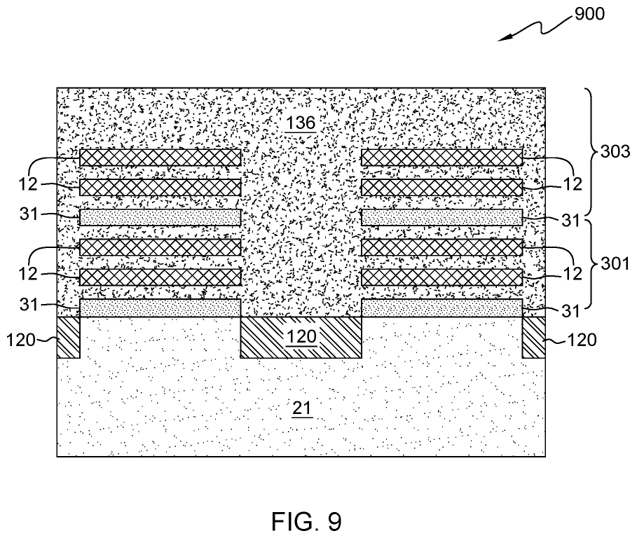

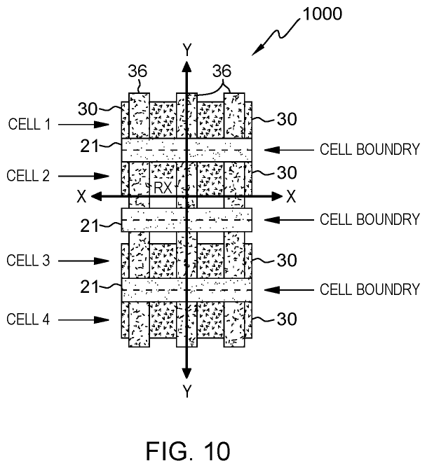

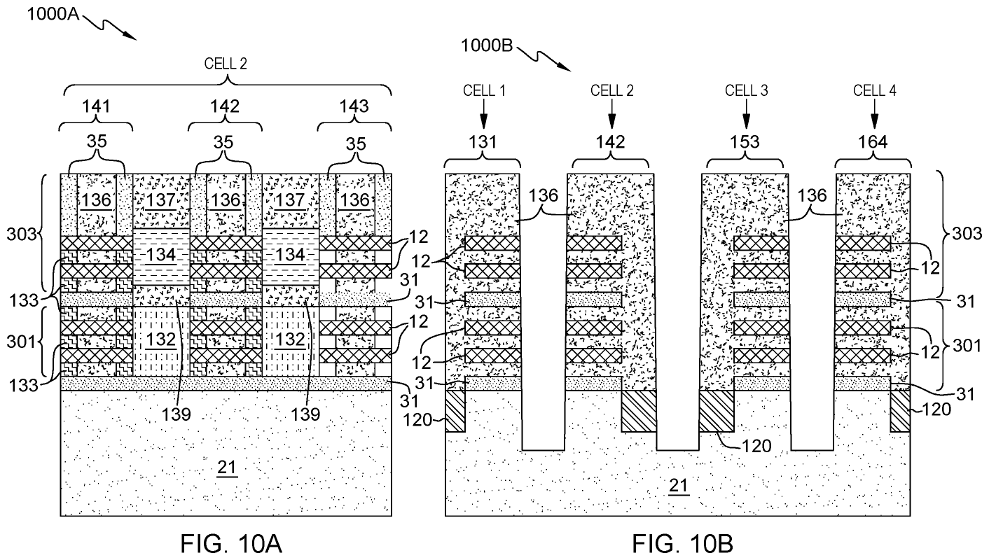

FIG. 9 depicts a cross-sectional view of the semiconductor structure in the through and parallel to gate 136 in the Y-Y direction depicted later in FIG. 10 after etching the nanosheet stack to form STI 120 and gate 136, in accordance with an embodiment of the present invention. Using the nanosheet stack processes as discussed with respect to FIG. 2 and the known semiconductor processes discussed in detail with respect to FIG. 3A, the nanosheet stack is etched to form two remaining portions of the nanosheet stack is etched and gate 136 is formed around the remaining portions of the nanosheet stack. In various embodiments, gate 136 is a replacement metal gate structure with a low-k gate dielectric. Gate 136 may be formed with the steps discussed in detail with respect to FIG. 3A from a dummy gate. In one embodiment, gate 136 is formed directly on the remaining portions of the nanosheet stack without forming a dummy gate.

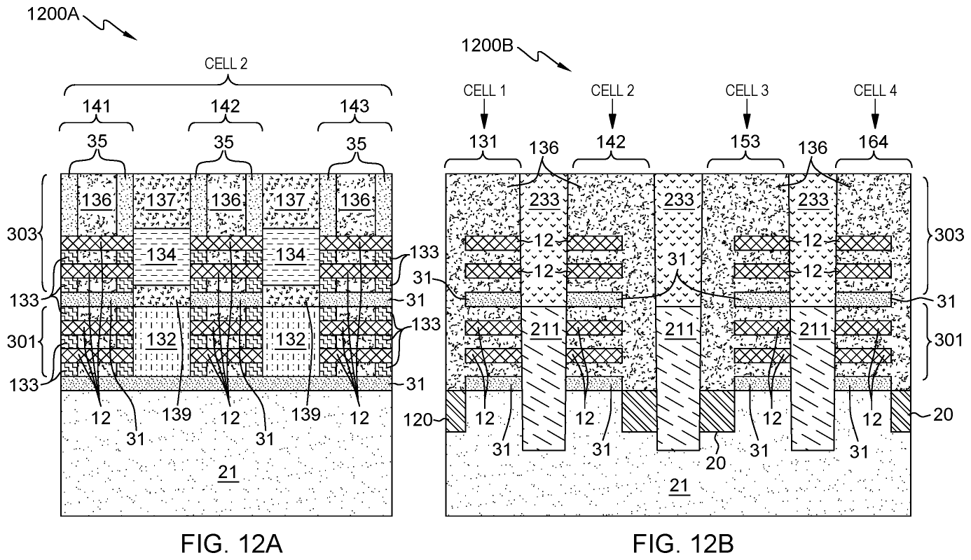

The two remaining nanosheet portions depicted in FIG. 9 have approximately the same footprint as the three remaining portions of the nanosheet stack depicted in FIG. 2. It is important to note that the two remaining portions of the nanosheet stack depicted in FIG. 9 will be divided to form four CFET devices in FIG. 12B. In this way, semiconductor structure 1200B can provide approximately a 30% reduction in the footprint size for three CFET devices as compared the footprint of the three CFET devices depicted in FIG. 7B.

As depicted, FIG. 9 includes STI 120 in semiconductor substrate 21, dielectric material 31 on portions of semiconductor substrate 21 and between the middle layers of channel material 12, gate 136, and brackets indicating the portions remaining portions of nanosheet stack (i.e., channel material 12) that will form the NFET and PFET of the CFET devices after later processes. The remaining portions of the nanosheet stack are labelled as nanosheet portion 301 which is under nanosheet portion 303. After later process steps, nanosheet portions 301 and 303 will each become four transistors (four upper transistors 303 and four lower transistors 301) of four CFET devices (e.g., CFET 131, CFET 142, CFET 153, and CFET 164 depicted later in FIG. 10B).

FIG. 10 depicts a top view 1000 of the semiconductor structure of FIG. 9 after forming a gate cut bisecting each layer of channel material 12 and in gate 136 between the remaining portions of channel material 12, in accordance with an embodiment of the present invention. As depicted, FIG. 10 includes gate 136, cell 1, cell 2, cell 3, cell 4, cell boundaries identified by dashed lines, active area 30 where each active area 30 is bisected by a gate cut exposing a portion of semiconductor substrate 21 and a third gate cut occurs between two of active area 30 also exposes a portion of semiconductor substrate 21. As known to one skilled in the art, active area 30 identifies the location of the remaining portions of the nanosheet stack composed of channel material 12 with dielectric material 31 and portions of gate 136 (not depicted in FIG. 10).

FIG. 10A depicts a cross-sectional view in the X-X direction of semiconductor structure 1000A after forming the gate cuts in portions of channel material 12 (not depicted in this view) and in a portion of gate 136 between two adjacent cells (not depicted), in accordance with an embodiment of the present invention. As depicted, FIG. 10A includes semiconductor substrate 21, the remaining portions of the layers of channel material 12, ILD 139 separating bottom S/D 132 and top S/D 134, ILD 137, gate 136 with gate spacer 135 and inner spacers 133. Also, illustrated in FIG. 10A are CFET 141, CFET 142, and CFET 143 of cell 2. As previously discussed, gate 136 can be a gate structure of a replacement metal gate. The gate cuts through the top of gate 136 bisecting channel material 12 and between channel material 12 extending down into semiconductor substrate 21 are not depicted in FIG. 10A.

FIG. 10B depicts a cross-sectional view in the Y-Y direction of semiconductor structure 1000B after forming the gate cut in each of the remaining portions of channel material 12 and in a portion of gate 136 between the remaining portions of the channel material 12 in CFET 142 and CFET 153, in accordance with an embodiment of the present invention. As depicted, FIG. 10B includes the elements of FIG. 9 with three gate cuts removing portions of semiconductor structure 900. The two outside gate cuts remove center portions of channel material 12, dielectric material 31, gate 136 over the center portions of channel material 12, and semiconductor substrate 21 under the center portion of channel material 12. The middle gate cut removes the portion of gate 136 between the remaining portions of channel material 12 depicted in FIG. 9, a portion of the middle STI 120 under a portion of gate 136, and a portion of semiconductor substrate 21 under the removed portion of STI 120. The gate cuts remove portions of semiconductor structure 1000B to form trenches extending into a portion of semiconductor substrate 21 between cell 1 and cell 2, cell 2 and cell 3, and cell 4, as depicted.

After removing the portions of semiconductor structure 900 with the gate cuts, four cells of CFET devices are formed. As depicted, cell 1 includes at least CFET 131, cell 2 includes at least CFET 142, cell 3 includes at least CFET 153, and cell 4 includes at least CFET 164. As previously discussed, a cell, in general, includes multiple CFET devices.

In FIG. 10B, each of the transistors are composed of either a top portion of the remaining channel material 12 (labelled nanosheet portion 303 in FIG. 9) or a bottom portion of the remaining channel material 12 (labelled nanosheet portion 301 in FIG. 9). The pair of transistors formed from nanosheet portions 303 and 301 that are over and under each other form one of CFET 131. CFET 142, CFET 153, and CFET 164. As depicted in FIG. 10B, the sidewalls of the remaining portions of channel material 12 in CFET 131 and CFET 142 directly adjacent to or abutting the gate cut are exposed (e.g., a portion of facing sidewalls of the CFET devices in adjacent cells 1 and 2 are exposed by one of the gate cuts). Similarly, a portion of the sidewalls of the devices in adjacent cells 3 and 4 are exposed by the rightmost gate cut. The center gate cut in FIG. 10B removes a center portion of gate 136 between cell 2 and cell 3 along with a portion of STI 120 and semiconductor substrate 21. After completing the gate cuts, CFET 131 in cell 1, CFET 142 in cell 2, CFET 153 in cell 3, and CFET 164 in cell 4 are formed. Each of CFET 131, 142, 153, and 164 include transistors 303 over transistors 301. Hereinafter, nanosheet portions 301 and nanosheet portions 303 will be called transistors 301 and transistors 303, respectively. In various embodiments, each pair of transistors 301 and transistors 303 directly above and below each other form a CFET device. As known to one skilled in the art, transistors 301 and transistors 303 in each CFET device (e.g., CFET 131, 142, 153, and 164) are a pair of complementary transistors (i.e., an NFET and a PFET).

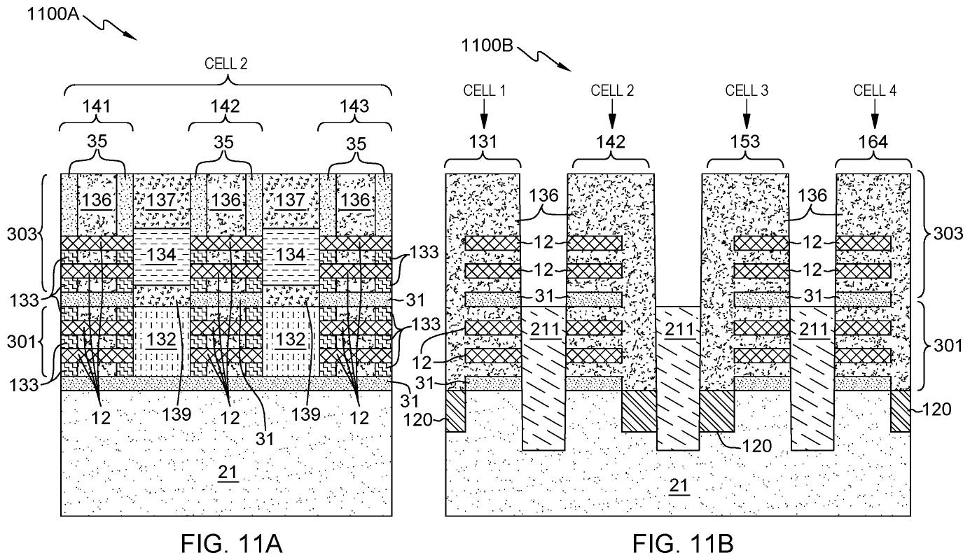

FIG. 11A depicts a cross-sectional view in the X-X direction of semiconductor structure 1100A after depositing a first dielectric material (not depicted) in the gate cuts (not depicted), performing a chemical-mechanical polish (CMP), and removing a portion of the first dielectric material in each cut, in accordance with an embodiment of the present invention. As depicted, FIG. 11A includes the elements of FIG. 10A.

FIG. 11B depicts a cross-sectional view in the Y-Y direction of semiconductor structure 1100B after depositing first dielectric material 211, performing a CMP, and removing the top portion of first dielectric material 211 in each gate cut, in accordance with an embodiment of the present invention. As depicted, FIG. 11B includes the elements of FIG. 10B with a portion of first dielectric material 211 in remaining in the lower portion of each gate cut. Semiconductor structure 1100B may be formed using the semiconductor processes previously discussed in detail with respect to FIGS. 5A, 6A, and 6B. As depicted, the level of the top surface of first dielectric material 211 is approximately equal to or level with a portion of the top layer of dielectric material 31 (e.g., between transistors 301 and transistors 303).

First dielectric material 211 abuts the exposed sidewalls of transistors 301 in both of cell 1, cell 2, cell 3, and cell 4 along with filling the bottom portion of the middle gate cut in gate 136 between cell 2 and cell 3. First dielectric material 211 is also abutting an upper portion semiconductor substrate 21 in each gate cut and in the middle gate cut, abuts a portion of STI 120.

First dielectric material 211 is selected to have a fixed charge with a polarity that enhances the electrical performance of each of transistors 301. Because the exposed edges of channel material 12 in transistors 301 are not in direct contact with a portion of gate 136, the electrostatics of this region of transistors 301 are not as good as the electrostatics of the regions of transistor 201 in contact with gate 136. To improve the electrostatics of this region, first dielectric material 211 is selected with a fixed charge that will improve the electrostatics of transistors 301. For example, when transistors 301 is a PFET, first dielectric material 211 is selected to provide a positive fixed charge (e.g., SiN) so that first dielectric material 211 effectively increases Vt (the voltage) of cut edges of transistors 301 (e.g., the exposed edges of channel material 12). In this way, first dielectric material 211 with a positive fixed charge improves the electrostatics of transistors 301. Similarly, when transistors 301 is an NFET, first dielectric material 211 is selected to have a negative change (e.g., SiN, Al₂O₃) so that first dielectric material 211 increases Vt in the vicinity of the exposed edges of transistors 301 (NFET) and thereby, improves the electrostatics of the region of transistors 301.

FIG. 12A depicts a cross-sectional view of the semiconductor structure in the X-X direction after depositing a second dielectric material and performing a CMP, in accordance with an embodiment of the present invention. As depicted, FIG. 12A includes the elements of FIG. 11A. First dielectric material 211 and second dielectric material 233 are not depicted in FIG. 12A.

FIG. 12B depicts a cross-sectional view in the Y-Y direction of semiconductor structure 1200B after depositing second dielectric material 233 and performing the CMP, in accordance with an embodiment of the present invention. As depicted, FIG. 12B includes the elements of FIG. 11B and second dielectric material 233 on first dielectric material 211 in each of the gate cuts. In various embodiments, the bottom surface of second dielectric material 233 on first dielectric material 211 is approximately level with the upper layer of dielectric material 31. Second dielectric material 233 abuts the exposed sidewalls of transistors 303. Second dielectric material 233 is in contact with the exposed portions of channel material 12 sidewalls and portions of gate 136 in transistors 303 in a portion of CFET 131 and CFET 142 (e.g., in adjacent cell 1 and cell 2) and in a portion of CFET 153 and CFET 164 (e.g., in adjacent cell 3 and 4).

Second dielectric material 233 is selected to have a fixed charge with a polarity that enhances the electrical performance of each of transistors 303. Because the exposed edges of channel material 12 in transistors 303 are not in direct contact with a portion of gate 136, the electrostatics of this region of transistors 303 are not as good as the electrostatics of the regions of transistor 201 in contact with gate 136. To improve the electrostatics of this region of each transistors 303, second dielectric material 233 is selected with a fixed charge that will improve the electrostatics of transistors 303.

For example, when transistors 303 is an NFET, second dielectric material 233 is selected to have a negative change (e.g., Al₂O₃) so that second dielectric material 233 increases Vt in the vicinity of the exposed edges of transistors 303 (NFET) and thereby, improves the electrostatics of the region of transistors 303.

Similarly, when transistors 303 is a PFET, second dielectric material 233 is selected to provide a positive fixed charge (e.g., SiN) so that second dielectric material 233 effectively increases Vt (the voltage) of cut edges of transistors 303 (e.g., the exposed edges of channel material 12). In this way, second dielectric material 233 with a positive fixed charge improves the electrostatics of transistors 303 (PFET).

Additionally, more CFET devices can be formed in FIG. 12B within approximately the same footprint as previously formed the CFET devices in FIG. 7B (4 CFET devices are formed in FIG. 12B in approximately the same area as the three CFET devices depicted in FIG. 7B). By forming CFET 131 in cell 1 and CFET 142 in cell 2 by bisecting the leftmost remaining portions of the nanosheet stack depicted in FIG. 9 (i.e., bisecting a portion of each layer of channel material 12) and forming CFET 153 in cell 3 and CFET 164 in cell 4 by bisecting the rightmost remaining portions of the nanosheet stack depicted in FIG. 9, the area required by the four CFETs of FIG. 12B is less than the area used by four traditionally formed CFET devices.

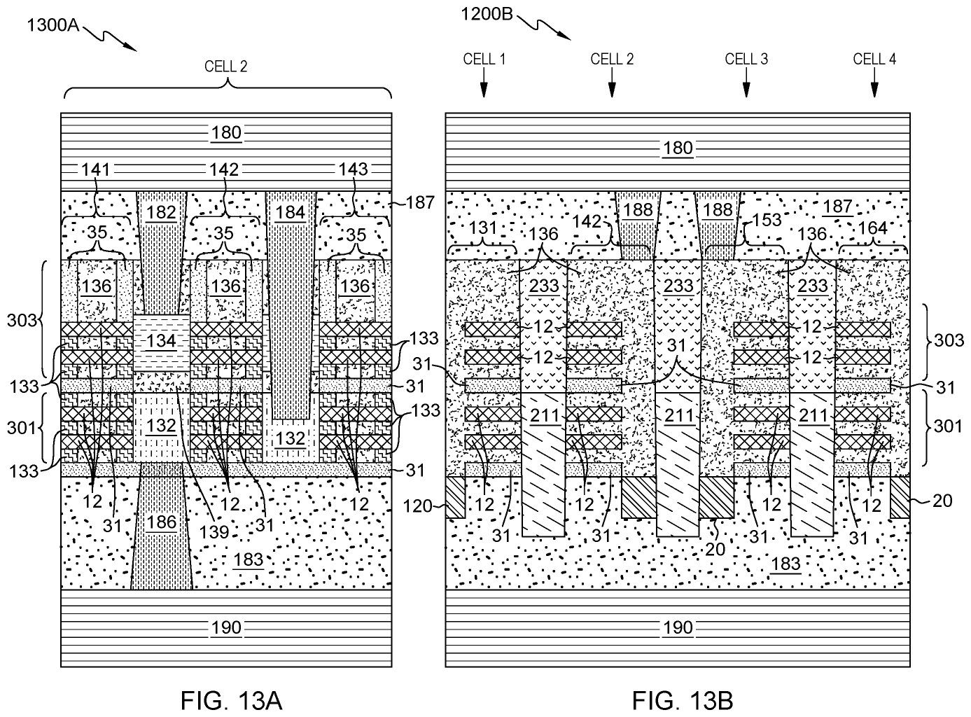

FIG. 13A depicts a cross-sectional view in the X-X direction of semiconductor structure 1300B after depositing frontside ILD 187, forming frontside contacts 182 and 184 connect top S/D 134 and bottom S/D 134 with frontside interconnect layers 180, carrier wafer bonding, semiconductor substrate 21 removal, depositing a backside ILD 183, forming backside contact 186 to the bottom S/D 132, and forming backside interconnect layers 190, in accordance with an embodiment of the present invention. Using known BEOL semiconductor processes as previously discussed with respect to FIG. 8A, semiconductor structure 1300A is formed. As depicted, FIG. 13A includes the elements of FIG. 12A and frontside contacts 182 and 184, frontside ILD 187, frontside interconnect layers 180, backside contact 186, and backside ILD 183.

FIG. 13B depicts a cross-sectional view in the Y-Y direction of semiconductor structure 1300B after depositing the frontside ILD 187, forming gate contacts 188 with frontside interconnect layers 180, carrier wafer bonding, semiconductor substrate 21 removal, depositing the backside ILD 183, and forming backside interconnect layers 190, in accordance with an embodiment of the present invention. As depicted, FIG. 13B includes the elements of FIG. 12B and gate contact 188, frontside ILD 187, frontside interconnect layers 180, backside ILD 183, and backside interconnect layers 190.

As previously discussed in detail, semiconductor structure 1300B provides more densely packed CFET devices than conventionally formed CFET devices by removing a portion of the gate extension between adjacent cells of CFET devices and depositing a dielectric material in the portion of the gate cut directly adjacent to the exposed portions of channel material 12 in each transistor (i.e., each of transistors 301 and 303 in each CFET device) with a fixed charge that improves the electrostatics of the region of channel material 12 not in direct contact with gate 136 in each of transistors 301 and 303. First dielectric material 211 abutting transistors 301 is selected to provide one of a negative charge to the exposed edges of channel material 12 in each of transistors 301 or to provide a positive charge to the exposed edges of channel material 12 depending on the type of transistors 301 is (i.e., a negatively charged dielectric material for NFETs and a positively charged dielectric for PFETs). Second dielectric material 233 is similarly selected to improve the electrical performance of transistors 303 in CFETs 131, 142, 153, and 164 in FIG. 13B.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a complementary field-effect transistor device with a first transistor under a second transistor, and
a gate cut directly adjacent and abutting a gate of the complementary field-effect transistor device, where the gate cut is filled with a first dielectric material under a second dielectric material.

2. The semiconductor structure of claim 1, wherein the first dielectric material applies a stress to one or more channels of the first transistor, the stress selected from the group consisting of: a compressive stress and a tensile stress.

3. The semiconductor structure of claim 2, wherein the first dielectric material applies the tensile stress to the one or more channels of the first transistor and the first transistor is an n-type field-effect transistor (NFET).

4. The semiconductor structure of claim 2, wherein the first dielectric material applies the compressive stress to the one or more channels of the first transistor and the first transistor is a p-type field-effect transistor (PFET).

5. The semiconductor structure of claim 1, wherein the first transistor is an NFET, the second transistor is a PFET, and the second dielectric material applies a compressive stress to one or more channels of the second transistor.

6. The semiconductor structure of claim 1, wherein the first transistor is an PFET, the second transistor is an NFET, and the second dielectric material applies a tensile stress to the one or more channels of the second transistor.

7. The semiconductor structure of claim 1, wherein the gate cut extends from a top surface of the gate of the complementary field-effect transistor device into a portion of a semiconductor substrate under the complementary field-effect transistor device.

8. The semiconductor structure of claim 1, wherein the gate cut is abutting a sidewall of the gate of the complementary field-effect transistor device, and wherein the first dielectric material under the second dielectric material is adjacent to the first transistor.

9. The semiconductor structure of claim 2, wherein the gate of the complementary field-effect transistor device directly contacts each channel of the one or more channels of the first transistor and the second transistor.

10. The semiconductor structure of claim 2, wherein a bottom portion of the gate of the complementary field-effect transistor device is between the one or more channels of the first transistor and the first dielectric material, and wherein a top portion of the gate of the complementary field-effect transistor device is between the one or more channels of the second transistor and the second dielectric material.

11. The semiconductor device structure of claim 1, wherein the first transistor is electrically isolated from the second transistor by at least one layer of a middle dielectric isolation material.

12. The semiconductor structure of claim 1, further comprising:
a first top contact connecting a top surface of a source/drain of the first transistor to a plurality of frontside interconnect layers;
a second top contact connecting a top surface of a source/drain of the second transistor to the plurality of frontside interconnect layers; and
a gate contact connecting a bottom surface of the source/drain of the second transistor to a plurality of backside interconnect layers.

13. The semiconductor structure of claim 1, wherein the first transistor and the second transistor are both a gate-all-around transistors, and wherein each channel layer of the first transistor and the second transistor are a layer of a nanosheet stack.

14. A semiconductor structure comprising:
a plurality of cells of complementary field-effect transistor (CFET) devices, wherein the CFET devices each have a top transistor under a bottom transistor,
a first dielectric material abuts a portion of each channel in the top transistor of a first CFET device in a first cell of the CFET devices and abuts a portion of each channel in the top transistor of a second CFET device in a second cell of the CFET devices adjacent to the first cell, wherein the first dielectric material has a fixed charge with a first polarity; and
a second dielectric material abuts a portion of each channel in the bottom transistor of the first CFET device in the first cell of the CFET devices and abuts a portion of each channel in the bottom transistor of the second CFET device in the second cell of the CFET devices, wherein the second dielectric material has the fixed charge with a second polarity.

15. A method of forming a complementary field-effect transistor (CFET) device, the method comprising:
epitaxially growing a nanosheet stack on a semiconductor substrate;
selectively etching the nanosheet stack and a top portion of the semiconductor substrate;
forming shallow trench isolations (STI) in the semiconductor substrate adjacent to remaining portions of the nanosheet stack;
forming at least two stacked gate-all-around field-effect transistors separated by a middle dielectric isolation material on the semiconductor substrate, wherein more than one first transistor is under the middle dielectric isolation material and more than one second transistor is above the middle dielectric isolation material;
performing gate cuts through a portion of each gate that is between the more than one first transistors and more than one second transistors, wherein the gate cuts go through the STI adjacent to the more than one first transistors and the top portion of the semiconductor substrate;
filling the gate cuts with a first dielectric material;
recessing the first dielectric material;
depositing a second dielectric material; and
performing a planarization.

16. The method of claim 15, further comprising:
forming top contacts and a plurality of top interconnection layers;
forming a back contact for the complementary field-effect transistor device; and
forming a plurality of bottom interconnect layers connected to a bottom contact.

17. The method of claim 15, wherein forming the at least two stacked gate-all-around field-effect transistors separated by the middle dielectric isolation material on the semiconductor substrate further comprises:
forming dummy gates above each shallow trench isolation and on and around portions of the remaining portions of the nanosheet stack;
removing two layers of a first sacrificial material in the remaining portions of the nanosheet stack;
conformally depositing a dielectric isolation material where a first sacrificial dielectric material was and around the dummy gates,
removing horizontal portions of the dielectric isolation material to form a bottom dielectric isolation on the semiconductor substrate, a middle dielectric isolation in a middle area of the nanosheet stack, and gate spacers around the dummy gates;
selectively removing portions of the remaining portions of the nanosheet stack between the dummy gates;
laterally etching an outer edge of a second sacrificial material of the two sacrificial materials;
forming inner spacers adjacent to remaining portions of the second sacrificial material;
epitaxially growing a bottom source/drain adjacent to a bottom portion of the remaining portions of nanosheet stack;
recessing the bottom source/drain;
depositing a dielectric material on the bottom source/drain;
epitaxially growing a top source/drain adjacent to a top portion of the remaining portions of nanosheet stack; and
performing the planarization.

18. The method of claim 15, wherein the first dielectric material creates a compression stress on a first transistor of the at least two stacked gate-all-around field-effect transistors and the more than one first transistor is a PFET.

19. The method of claim 15, wherein the second dielectric material creates a tensile stress on a second transistor of the at least two stacked gate-all-around field-effect transistors and the second transistor is an NFET.

20. The method of claim 15, wherein a PFET in the at least two stacked gate-all-around field-effect transistors is adjacent to a dielectric material that is creating a compressive stress on a plurality of channels of the PFET and an NFET in the at least two stacked gate-all-around field-effect transistors is adjacent to the second dielectric material that is creating a tensile stress on the plurality of channels of the NFET.
